(19) United States
(12) Patent Application Publication
(10) Pub. No.: US 2024/0062075 A1
(43) Pub. Date: Feb. 22, 2024

(54) METHODS FOR PREDICTION OF NEUTRONICS PARAMETERS USING DEEP LEARNING

(71) Applicants: Cole GENTRY, Oak Ridge, TN (US); University of Florida Research Foundation, Inc., Gainesville, FL (US)

(72) Inventors: Forrest SHRIVER, Gainesville, FL (US); Justin WATSON, Gainesville, FL (US); Cole Andrew GENTRY, Oak Ridge, TN (US)

(21) Appl. No.: 18/266,367

(22) PCT Filed: Dec. 9, 2021
(86) PCT No.: PCT/US2021/072844

§ 371 Date: Jun. 9, 2023

Related U.S. Application Data
(60) Provisional application No. 63/241,189, filed on Sep. 7, 2021.
(60) Provisional application No. 63/123,260, filed on Dec. 9, 2020.

(51) Int. Cl. G06N 3/0985; G06N 3/047

(52) U.S. Cl. CPC G06N 3/0985; G06N 3/047

(57) ABSTRACT

Various examples are related to prediction of neutronics parameters using deep learning. In one embodiment, a method includes generating a training data set based upon one or more principled approaches that provide a gradient of values; generating a neural network using structured or unstructured sampling of a hyperparameter space augmented by probabilistic machine learning; training the generated neural network based on the training data set to produce one or more neutronics parameters; and generating at least one neutronics parameter utilizing the trained neural network.

### CROSS REFERENCE TO RELATED APPLICATIONS

This application claims priority to, and the benefit of, co-pending U.S. provisional applications entitled “Methods for Prediction of Neutronics Parameters Using Deep Learning” having Ser. No. 63/123,260, filed Dec. 9, 2020, and Ser. No. 63/241,189, filed Sep. 7, 2021, both of which are hereby incorporated by reference in their entireties.

### STATEMENT REGARDING FEDERALLY SPONSORED RESEARCH OR DEVELOPMENT

This invention was made with government support under grant number DE-AC05-000R22725 awarded by The US Department of Energy. The government has certain rights in this invention.

### BACKGROUND

The simulation of light water reactors is usually performed using either high-fidelity methods (e.g., method of characteristics, Monte Carlo methods, finite elements) or low-fidelity methods such as nodal diffusion methods). In the case of high-fidelity methods, these codes are designed to run primarily on high-performance computing (HPC) clusters, possibly requiring hundreds of nodes for parallelization and multiple hours or even days to complete. Low-fidelity methods such as diffusion codes are intended to quickly run on commonly available computing hardware such as laptops or engineering workstations. Due to their very different computational natures, these codes naturally fall into two different application domains; high-throughput domains such as design optimization, and low-throughput domains such as confirmation analysis.

### SUMMARY

Aspects of the present disclosure are related to the prediction of neutronics parameters using deep learning. A neural network architecture has been developed for predicting reactor parameters such as, e.g., normalized pin powers within a single reflective 2D assembly of a pressurized water reactor.

In one aspect, among others, a method for generating neutronics parameters, comprises generating, by at least one computing device, a training data set based upon one or more principled approaches that provide a gradient of values; generating, by the at least one computing device, a neural network using structured or unstructured sampling of a hyperparameter space augmented by probabilistic machine learning; training, by the at least one computing device, the generated neural network based on the training data set to produce one or more neutronics parameters; generating, by the at least one computing device, at least one neutronics parameter utilizing the trained neural network. In one or more aspects, the structured or unstructured sampling can comprise Latin hypercube sampling (LHS). The probabilistic machine learning can comprise tree-structured Parzen estimators (TPE). The structured or unstructured sampling can be random. Operation of a reactor can be adjusted based upon the at least one neutronics parameter. In various aspects, the method can comprise testing the trained neural network based upon a defined set of input data associated with a known result. The known result can be symmetric function about the center of the evaluated region. The evaluated region can be a portion of a nuclear reactor core. Data of the training data set can be augmented by a lower order physical model.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIGS. 1A and 1B illustrate example of fine-mesh and course-mesh mappings for a two-vertex curved surface, in accordance with various embodiments of the present disclosure.

FIG. 2 illustrates an example of a basic multi-layer perceptron neural network architecture, in accordance with various embodiments of the present disclosure.

FIG. 3 illustrates an example of a basic convolutional neural network architecture, in accordance with various embodiments of the present disclosure.

FIG. 4 is a schematic diagram illustrate an example of Lattice Net, in accordance with various embodiments of the present disclosure.

FIG. 5 is a flowchart illustrating an example of an LHS/TPE search algorithm, in accordance with various embodiments of the present disclosure.

FIG. 6 is a flowchart illustrating an example of an ASHA adaptive pruning method, in accordance with various embodiments of the present disclosure.

FIG. 7 illustrates a comparison of LatticeNet variants using a small number of trials for hyperparameter optimization, in accordance with various embodiments of the present disclosure.

FIG. 8 is a plot illustrating training loss vs. number of epochs, in accordance with various embodiments of the present disclosure.

FIG. 9. Illustrates examples of average pinwise absolute error all samples and fuel group, in accordance with various embodiments of the present disclosure.

FIG. 10 illustrates a comparison of the average pinwise absolute error produced by the IFBA fuel group for the initial and updated versions of LatticeNet, in accordance with various embodiments of the present disclosure.

FIG. 11 illustrates an example of a distribution map of the individual pin power percentage error across all five folds of the final converged LatticeNet model, in accordance with various embodiments of the present disclosure.

FIG. 12 illustrates examples of distribution plots of the error in pcm between the actual and predicted k_{eff} values for the different fuel groups from the best-performing LatticeNet model, in accordance with various embodiments of the present disclosure.

FIG. 13 is a schematic diagram illustrate an example of stages of processing temperature distributions to generate a comparison, in accordance with various embodiments of the present disclosure.

FIG. 14 is a plot illustrating an example of pin power errors between MPACT/LatticeNet and CASMO-4E/SIMULATE-3, in accordance with various embodiments of the present disclosure.

FIG. 15 is a plot illustrating an example of k_{eff} errors in pcm between MPACT/LatticeNet and CASMO-4E/SIMULATE-3, in accordance with various embodiments of the present disclosure.

FIG. 16 is a schematic diagram illustrating an example of LatticeNet 1.0, in accordance with various embodiments of the present disclosure.

FIG. 17 illustrates a zoomed-in version of FIG. 16 focusing on the transition from the convolutional stack to the concatenation step for a single convolutional stack, in accordance with various embodiments of the present disclosure.

FIG. 18 illustrates a diagram outlining the relevant math when transitioning from the convolutional stack to the concatenation step for LatticeNet 1.1, in accordance with various embodiments of the present disclosure.

FIG. 19 illustrates a diagram outlining the relevant math when transitioning from the convolutional stack to the concatenation step for LatticeNet 1.2, in accordance with various embodiments of the present disclosure.

FIG. 20 illustrates a diagram outlining the relevant math when transitioning from the convolutional stack to the concatenation step for LatticeNet 1.3, in accordance with various embodiments of the present disclosure.

FIG. 21 illustrates a diagram outlining the relevant math when transitioning from the convolutional stack to the concatenation step for LatticeNet 1.4, in accordance with various embodiments of the present disclosure.

FIG. 22 illustrates examples of the high-level operations in different LatticeNet variants, focusing on a single convolutional stack, in accordance with various embodiments of the present disclosure.

FIG. 23 illustrates an example of average pinwise percent error of LatticeNet 1.0 for the 4×4 dataset, in accordance with various embodiments of the present disclosure.

FIG. 24 illustrates examples of average pinwise percent error of LatticeNet 1.1-1.4 for the 4×4 dataset, in accordance with various embodiments of the present disclosure.

FIG. 25 illustrates an example of upper bounds of the pinwise percent errors for LatticeNet 1.0 on the 4×4 dataset, in accordance with various embodiments of the present disclosure.

FIGS. 26 and 27 illustrate examples of extrapolated error and extrapolated training times for larger region sizes, in accordance with various embodiments of the present disclosure.

FIG. 28 illustrates examples of physically adversarial inputs generated, in accordance with various embodiments of the present disclosure.

FIG. 29 illustrates examples of error distribution and maximum pinwise error for samples with the moderator density behaving as outlined in Algorithm 1, in accordance with various embodiments of the present disclosure.

FIG. 30 illustrates examples of error distribution and maximum pinwise error for samples with the moderator density behaving as outlined in Algorithm 4, in accordance with various embodiments of the present disclosure.

FIG. 31 illustrates examples of error distribution and maximum pinwise error for samples with the fuel temperature behaving as outlined in Algorithm 1, in accordance with various embodiments of the present disclosure.

FIG. 32 illustrates examples of error distribution and maximum pinwise error for samples with the fuel temperature behaving as outlined in Algorithm 4, in accordance with various embodiments of the present disclosure.

FIG. 33 illustrates examples of error distribution and maximum pinwise error for samples with the clad temperature behaving as outlined in Algorithm 4, in accordance with various embodiments of the present disclosure.

FIG. 34 illustrates examples of plot answers provided by LatticeNet 1.1 for inputs with a steadily lowering centerline amplitude, in accordance with various embodiments of the present disclosure.

FIGS. 35 and 36 illustrate examples of evaluation of the RSSE of LatticeNet 1.1 and 1.2 for out-of-distribution clad temperatures values, in accordance with various embodiments of the present disclosure.

FIG. 37 illustrates examples of evaluation of the RSSE of all three LatticeNet variants for out-of-distribution fuel temperatures and moderator densities, in accordance with various embodiments of the present disclosure.

FIG. 38 is a schematic block diagram of an example of a computing device, in accordance with various embodiments of the present disclosure.

### DETAILED DESCRIPTION

Disclosed herein are various examples related to the prediction of neutronics parameters using deep learning. Current high-fidelity modeling and simulation codes are subject to high computing cost, which often makes them too expensive to be widely used for industry and small-scale user applications. LatticeNet is a neural network architecture which has been developed for predicting reactor parameters such as normalized pin powers within a single reflective 2D assembly of a pressurized water reactor. In this research, we investigate the computational performance of LatticeNet and the most efficient configurations when running a single model in inference mode across multiple cores. The results indicate that data-level parallelism is the best strategy for deployment of a trained LatticeNet model, and that full multi-score scaling in this manner is the most computationally efficient. Reference will now be made in detail to the description of the embodiments as illustrated in the drawings, wherein like reference numbers indicate like parts throughout the several views.

For confirmation analysis, high-fidelity methods are used to produce a description of the reactors evolution at a very high level of detail or to model complex coupled phenomena such as CRUD deposition. For design optimization, diffusion methods are a deterministic, conservative means to estimate reactor parameters used in core design studies in a computationally cheap manner, circumventing the need to apply the expensive models used by more high-fidelity methods. Multiple techniques attempt to reconcile the differences in accuracy between these two “levels” of fidelity, such as the two-step method with pin power reconstruction, which underlies most modern diffusion codes. However, for the most part, high-fidelity and low-fidelity techniques are still widely separated in terms of the applications for which they are used.

If a data-driven model can be developed that combines the strengths of high-fidelity and low-fidelity techniques while minimizing their negative aspects, such a model could be useful in multiple application domains. One example is as an auxiliary information system in design optimization applications, where the data-driven model provides an interpolated guess as to the value of a parameter of interest without needing to run an expensive high-fidelity solve. In this scenario, if an engineer has arrived at several designs which all satisfy the design criteria, they might then consult the data-driven model in order to make a final decision on which design is best, all other factors being equal. Another related application is in loading pattern screening, where a set of design patterns are run through the cheaper data-driven model with only the best-performing designs passed to an actual core simulator. It's notable that this particular application has already been demonstrated in an earlier form, although not at the level of fidelity we attempt to handle in this paper. It should be emphasized that in neither of these use cases is the data-driven model being used as an important component of the simulation pipeline, since most modern machine learning methods make no guarantee of accuracy. Instead, these models serve as a convenient tool for obtaining useful parameter estimations in a computationally expedient manner.

This disclosure proposes using neural networks as a data-driven models to generate predictions that are approximately high-fidelity with very low computational cost. There are multiple reasons motivating the use of neural networks instead of other machine learning methods. The first reason is the enormous success of neural networks in computer vision applications, in which certain network types have achieved great success in digit recognition and image classification. Because the design and state parameters in an assembly can be decomposed into multiple channels of information (discussed further in the Data Decomposition Section), it is an open question as to whether the techniques that have been applied in computer vision can also be applied successfully to the problem of parameter prediction. Another reason to use neural networks instead of other machine learning models is that GPU-based scientific computing has proliferated across different scientific domains to such a degree that multiple HPC facilities are including vector processing units as a core part of their current or projected capabilities. It is therefore worthwhile to investigate and develop methods that effectively leverage these capabilities, for which neural networks are uniquely suited due to their heavy use of matrix and vector operations.

Pressurized water reactors (PWRs) have been selected as the reactor type to be simulated by neural networks. Mature computational methods and engineering knowledge have been developed around these reactors, with high-fidelity codes such as MCNP, Serpent, and MPACT, thus allowing for the robust generation and collection of accurate high-fidelity data and comparison against other methods currently being used. Previous work in which neural networks have been applied to PWRs has focused exclusively on simulation of general reactor core parameters such as assembly powers, assembly pin power peaking factors, and k_{eff}. This work has been limited almost exclusively to consideration of simpler multi-layer perceptron (MLP) network architectures; there has been minimal investigation of more advanced neural network architectures such as convolutional neural networks (CNNs). The most significant and recent research on this application was performed in which the model is similar in structure to the Inception-v3 model, which is widely used for image recognition tasks. PinNet, the model used, was very deep, and it successfully predicted assembly powers and individual pin powers using image-based neural network techniques. However, because very deep networks are often expensive to train, this work considers smaller networks with very different architecture to be used as a first step. Additionally, while PinNet predicted individual pin powers accurately, it did so by interpolating on pre-computed form factor tables. The present research is novel in that the objective is to predict these high-fidelity features without such pre-computed libraries. This work is a proof-of-concept demonstrating these capabilities under a variety of assembly design scenarios which are of interest to both industry and research entities, such as varying burnable poison usage as well as varying types of burnable poisons used.

### Data

To generate the synthetic high-fidelity data used in this research, the VERA simulation suite—and more specifically the MPACT code package—was used to generate accurate pin-resolved powers under a variety of state conditions. This code package uses the method of characteristics to solve the steady-state neutron transport equation and is considered to be correct for most applications of interest. The VERA package is also ideal for use in this research due to its robust multi-physics coupling between MPACT and the thermal hydraulics code COBRA-TF (CTF), although these capabilities were not used in this work.

Data Generation. The data generated and used in this work were based on Problem 2 from the VERA Core Physics Benchmark Progression Problem Specifications, which are based on the Watts Bar Unit 1 reactor. This problem is a single 2D hot zero power (HZP) infinite fuel lattice with several different pin geometries and material compositions described to accommodate different burnable poisons such as gadolinia, integral fuel burnable absorber (IFBA), Pyrex, and wet annular burnable absorber (WABA). The variations allowed in this dataset included the variation of pinwise thermal hydraulic parameters (e.g., fuel temperature, clad temperature, coolant density), variation of the lattice enrichment level, variation of the presence/absence of control rods, variation of the soluble boron concentration, as well as the presence/absence of different burnable poisons. Multiple burnable poisons were not allowed in the same assembly in order to allow easy analysis of the error introduced by different burnable poison groups.

Thermal Hydraulic Parameters. The largest amount of variation allowed in this dataset was in the thermal hydraulic parameters: namely, fuel temperature, clad temperature, fuel pin moderator density, and guide tube moderator density. In a normal simulation, these parameters would have been predicted by the CTF code package incorporated into VERA, which would have iterated with the MPACT code to produce final thermal hydraulic and neutronic conditions. Instead, these parameters were provided to MPACT using a User Defined TH function that allows the user to manually provide assumed steady-state thermal hydraulic variables. In this case, the pinwise fuel temperatures were allowed to vary between 286-1,326 degrees Celsius, the pinwise clad temperatures were allowed to vary between 286-356 degrees Celsius, and the density of the fuel pin moderator and guide tube moderator was allowed to vary between 0.66 and 0.743. This approach provided a set of more varied conditions and their associated neutronics effects than might normally be encountered in order to provide the neural network with information on a large portion of the space instead of information relating to more normal conditions. The variations allowed in thermal hydraulic conditions are shown in Table I.

TABLE I
Summary of thermal hydraulic variations.

| Design parameter | Allowed Range |
|---|---|
| Fuel temperature (Celsius) | 286-1,326 |
| Cladding temperature (Celsius) | 286-356 |
| Moderator density (g/cc) | 0.660-0.743 |
| Guide tube density (g/cc) | 0.660-0.743 |

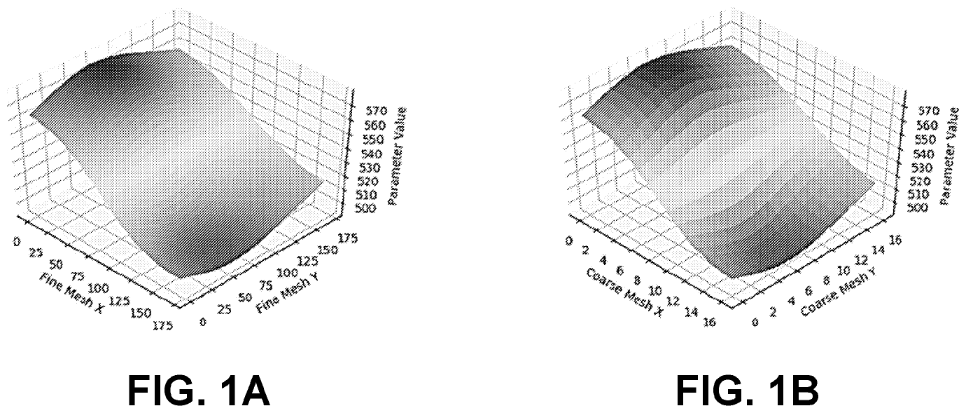

One problem with randomly sampling pinwise thermal hydraulics parameters is that a purely random pin-wise sampling method will result in highly nonphysical and statistically uninformative noisy distributions. To resolve this, a curved surfaces method was used to provide a more informative statistical distribution from which the neural network would “learn.” In this method, a random number of vertices between 1 and 3 were selected in a uniformly random manner on the parameter range desired. These vertices were then placed randomly on a fine mesh grid. After all vertices had been placed, the value of each point on the fine mesh was then computed as a weighted sum of the various vertex points, where the weight is the inverse squared distance between the point and all vertices. Finally, once this fine mesh was created, the per-pin values were computed by downsampling onto the desired grid size, in this case a 17×17 grid corresponding to the single fuel assembly. In this way, random distributions of thermal hydraulic variables were created that more closely approximate physical scenarios than random pinwise sampling. While the variables are still physically non-realistic compared to using an actual thermal hydraulics model, this method decreases the entropy in the dataset and allows the network to learn from response surfaces instead of learning from what is effectively white noise in the case of a uniform random distribution. It's worth mentioning that the different thermal hydraulics features (fuel/clad temperatures and fuel/guide tube moderator densities) were allowed independent curves, in an effort to more broadly cover the possible state space. An example of a randomly generated fine mesh, as well as the resulting downsampled 17×17 parameter grid, can be found in FIGS. 1A and 1B.

Lattice Enrichment. As mentioned above, the ²³⁵U enrichment was allowed to vary between 1.8 and 4.9%, where a single randomly generated enrichment was used for all pins within a given assembly design. While variation of the pin enrichment within a lattice is possible, this limitation was enforced as this is paper demonstrates a proof-of-concept paper and as most commercial reactors use a uniform enrichment per assembly. Of note is that there was one special case regarding this rule: fuel pins that contained gadolinia were set with a ²³⁵U enrichment of 1.8%, regardless of the lattice enrichment selected. This was done to keep all burnable poison designs in line with those detailed, and represents a first step towards attempting to predict on more computationally complex gadolinia-loaded designs. This limitation may not be necessary in modern fuel designs, and may include variations on this constraint for Gadolinia-containing assemblies.

State Conditions. The state conditions generated in the dataset are primarily associated with parameters such as control rod position and soluble boron concentration. In the case of the control rod position, this was varied by randomly altering the assembly state to either have the control rods fully in (1) or fully out (0), with the Pyrex and WABA fuel groups holding this at 0 since assemblies with these burnable poisons would not be placed in positions with control rods. In the case of the soluble boron concentration, the concentration was allowed to vary randomly between 0 and 2,000 parts per million.

Burnable Poisons. As previously mentioned, the fuel pin/guide tube design of all four burnable poisons (gadolinia, IFBA, Pyrex, WABA) was kept the same as that previously described in Godfrey's Problem 2. In the case of the IFBA, Pyrex, and WABA burnable poisons, the placement was performed randomly within the fuel assembly using octant symmetry. Since gadolinia as a burnable poison is very opaque and complex to accurately model, use of a random placement scheme was found to be problematic, as it was found to be quite easy to “over-gad” the fuel assembly design, leading to significantly repressed neutronics parameters. The overall effect of this over-gadding was an increase of LatticeNet's error relative to all other burnable poisons used. To resolve this issue, gadolinia poison placement was restricted to the locations described originally in the specification. Since there are only two gadolinia placement patterns described by Problem 2-12-pin and 24-pin—publicly available designs from the European Pressurized Reactor (EPR) were used to supply three additional placement patterns: 8-pin, 16-pin, and 20-pin. Thus the data generated and used in this research can be divided into five distinct groups based on burnable poison content: a gadolinia group, an IFBA group, a Pyrex group, a WABA group, and a fifth No Poison group which contained no burnable poisons. Again, no assemblies that are in one burnable poison group were allowed to possess burnable poisons from another group. A summary of the different burnable poison groups and their corresponding configurations is shown in Table II.

TABLE II
Summary of burnable poison variations; CR = control rod, GT = guide tube, FP = fuel pin.

| | Burnable poison group | | | | |
|---|---|---|---|---|---|
| Design parameter | No poison | Gadolinia | IFBA | Pyrex | WABA |
| CR position | 0, 1 | 0, 1 | 0, 1 | N/A | N/A |
| GT placement | N/A | N/A | N/A | [0-24] pins | [0-24] pins |
| FP placement | N/A | 8, 12, 16, 20, 24 pins | [4-289] pins | N/A | N/A |

Data Decomposition. One of the fundamental assertions of this work is that the task of developing a regression model for predicting high-fidelity features given a set of fuel/poison loadings and state conditions can be thought of as a problem fundamentally similar to computer vision applications. Imagine the simple problem of a 2D HZP assembly similar to that used to generate the data used in this research. In this example, the lattice enrichment is unchanging, there are no burnable poisons, the control rods are fully withdrawn, and the soluble boron concentration is kept at a constant value. Therefore, the only parameters that can possibly change are the fuel and cladding temperature as well as the moderator density around the fuel pins and inside of the guide tubes. When examined separately, each parameter can be thought of as a 2D array of values very similar to an image of the specific parameter values at each pin location, where one pin is equivalent to one pixel. From just this simple example, there are therefore four channels of information similar to the red-green-blue channels of information found in image processing applications. The addition of scenario states such as changing uranium enrichment or the presence/absence of burnable poisons can then be thought of as adding in new channels of information in addition to thermal hydraulic information.

CNNs, which are discussed further in the Convolutional Neural Networks Section, have had great success in applications that use computer vision or 2D spatial data in some manner due to their specialized architecture. One of the restrictions imposed by CNNs, however, is that (for 2D convolutional architectures) the data should be represented in a 2D manner. Additionally, CNNs usually look for the same feature in a stack of channel information; for normal 2D images this makes sense, as the red-green-blue channel information is usually related. However, for neutronics parameter regression it is not clear that this is the best approach, especially as different channels of information may have very different features. For example, temperature difference features in no way affect changes in pin placement within the context of an already-determined assembly design. Therefore, when developing an architecture for parameter regression, all relevant information should be present in a coherent manner, and the channels of information should be sufficiently distinct from each other.

The thermal hydraulic parameters are relatively straightforward to decompose, as they follow directly from the previous example; the different parameters are reshaped into a 2D 17×17 array and fed into the network as completely separate channels of information (designated stacks hereafter). Of note is that the moderator density within the guide tubes does not necessarily need a full 17×17 representation, as the “image” will only have values at the guide tube locations and will be zero everywhere else. For ease of exploration, however, these values were still shaped into a 17×17 format, although special attention was paid when designing convolutional operations to operate on these and other parameter stacks that possess values only in guide tube locations, as detailed further in the Convolutional Neural Networks Section.

The ²³⁵U enrichment parameter is also similarly simple to decompose, as the information for this parameter can be posed as a 2D image composed of pin enrichment values. For the data used in this work, it is worthwhile to note that if the gadolinia burnable poison group were not included, then the enrichment parameter could likely be reduced to a single parameter value with no loss of information, as the lattice enrichment is uniform across all pins. The inclusion of gadolinia, however, prompts a change of the ²³⁵U enrichment in the corresponding design, prompting the formatting of the ²³⁵U enrichment parameter as a 2D pattern. Moreover, this network may be trained and tested on scenarios that contain intra-pin enrichment variation. To accommodate these goals, the enrichment can therefore be placed in a 2D format for this research, although special attention was paid to this stack when designing its convolution operations.

The gadolinia, IFBA, Pyrex, and WABA stacks are not as straightforward to decompose since each has several associated descriptors, such as coating thickness and coating density in the case of the IFBA burnable poison, and gadolinium loading in the case of the gadolinia burnable poison. Since all burnable poison designs were kept consistent with those previously described, the burnable poison information is decomposed into separate stacks for each burnable poison type, with 2D arrays of values consisting of either 0 or 1. It could be expanded to include variations on burnable poison designs; in this case, it should be straightforward to further decompose these burnable poison designs into channels of information that more accurately describe the burnable poisons in question.

Finally, the control rod position and boron concentration should be decomposed. Since MPACT considers the soluble boron concentration to be uniform, and since the control rods within a 2D assembly can be considered either fully inserted or fully withdrawn, these parameters can most simply be decomposed as scalar variables. Since there are no plans to change the soluble boron model within MPACT in the near future, and since a 2D assembly/set of assemblies will always represent the control rods as fully inserted/withdrawn, the decision was made to form these parameters into a single scalar stack. The details of how these and other stacks were ultimately designed can be found in the LatticeNet Section.

### Neural Networks

The objective of any machine learning model can be thought of as attempting to model the “true” underlying function of a set of data, F(x), with a surrogate function f*(x). Neural networks make the assertion that this surrogate function f*(x) can be represented as a series of transformations fⁿ(x), where fⁿ is the n-th transformation of the input data x. In neural networks, each transformation in these layers of transformations is not a single continuous-valued transformation, but is rather a series of independent vector-to-scalar transformations of the input provided by the previous transformation layer (or the network input). Within a single transformation, each of these independent vector-to-scalar transformation units is referred to as a neuron. The transformation imposed by each neuron is inherently linear, so it cannot represent non-linear components. To resolve this, all neurons within a given layer usually apply an activation function to their scalar output. Traditional neural networks are therefore at their core a series of linear and non-linear vector transformations of an input vector x to an output vector f*(x); common architectures only differ in the manner in which individual neurons are connected. For the interested reader, there are multiple texts which discuss in detail the methods and implementation of neural networks.

While the basic description of neural networks is simple enough, the methods used by these networks to learn is slightly more complicated. Individual neurons perform a transformation of their input (the previous layer's output) by multiplying the appropriate vector components by a weight which is randomly generated and unique for each vector component. These randomly generated weights have no guarantee of being in the correct distribution for accurate prediction initially; neural networks therefore go through a corresponding training phase in which a given input is forward-propagated through the successive layers and their weights. The error gradient for each weight is then computed w.r.t. the error between the network output and the correct output in a process known as back-propagation. To gain a better idea as to the distribution of error and to improve computational efficiency, the data are usually provided in mini-batches composed of a given number of samples to the network, in which the error gradients for each weight are computed in aggregate over the entire batch. These aggregated gradient values are then passed to an optimization algorithm which is responsible for intelligently updating the neuron weights to most effectively minimize the error between the network output and the correct output for all samples within the batch. A single loop over all of the training data, where the data are divided into #samples/batch size batches, is therefore known as an epoch. Neural networks may need to be trained for a few hundred to a few hundred thousand epochs before being tested on separate data, depending on parameters such as network architecture and researcher preference.

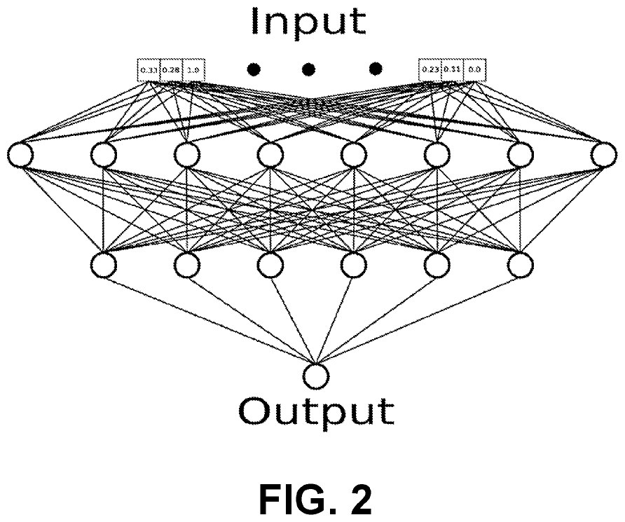

Multi-Layer Perceptrons. Multi-layer perceptrons (MLPs) are one of the most commonly known neural network architectures, originally proposed in the 1950s and commonly used in early machine learning applications. In these networks, all neurons within a layer are connected to all neurons in the previous layer in what is known as a fully connected or densely connected (dense) architecture. These neural networks are not able to directly account for spatial information within an input, as they require all data to be fed in as a one-dimensional vector. For applications sensitive to spatial information, these networks by themselves are insufficient, as they have no way to process spatial information. However, they are still useful for the transformation of scalar features and for regression of extracted features against an output vector. An example of a simple MLP architecture is shown in FIG. 2.

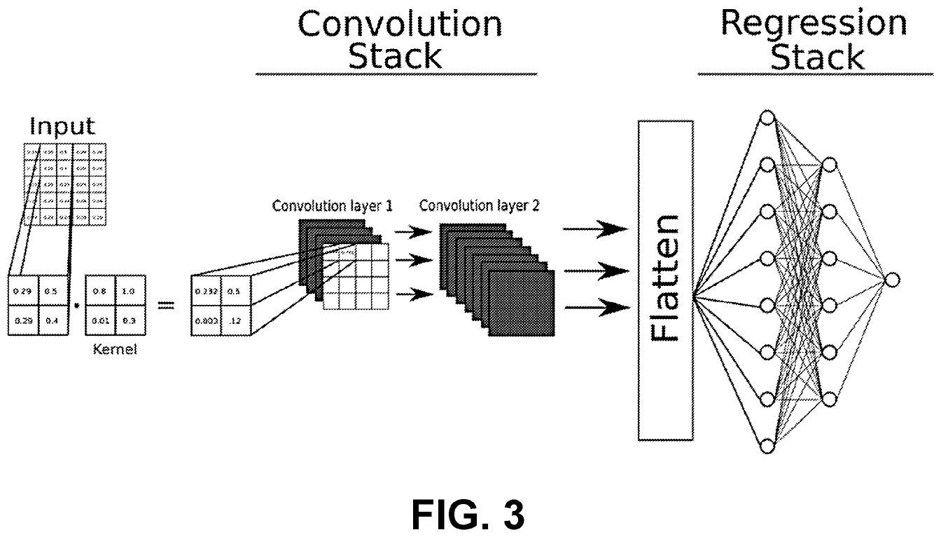

Convolutional Neural Networks. Convolutional neural networks (CNNs) were originally proposed in the 1990s for digit recognition on a dataset provided by the US Postal Service and have since been applied as a significant component of many computer vision network architectures. CNNs are fundamentally different from MLPs in that they (usually) require the data to be shaped into some spatial structure, and they do not require successive layers to be fully connected. Instead, they search for spatial features within the input. In the example of a CNN using a two-dimensional convolution, a feature is represented by an n x m kernel which is multiplied by the values at a given spatial section of an input. This kernel “slides” across the image, being multiplied by the values at every spatial section and then summed to produce a two-dimensional feature map or filter, indicating the presence of the feature within each n×m section of the input. Since a single filter may not be enough to describe all relevant features within an image, a single convolutional layer is usually composed of multiple filters, each of which corresponds to a different kernel and thus selects for different features. Multiple convolutional layers are usually successively stacked on top of each other, and the filtered feature maps produced by one convolutional layer are used as the spatial input data for the next layer. A set of stacked layers is usually referred to as a convolution stack. An example of a basic CNN architecture is shown in FIG. 3, where the direct multiplication and summation of a spatial region into a feature map is shown.

It is worth noting that a CNN is usually composed of additional components to the convolution stack. One component usually included as part of the convolution stack is the max pooling layer, which removes some spatial information in order to provide more information about the presence of a feature globally within the input. These layers enforce a notion of the translation invariance of extracted features, and they assume that the location of a feature in the input is not as important as whether it is there or not. The analysis holds that global identification of feature presence is not useful in the context of capturing features that are highly local, such as the fuel temperature of pins close to each other, and so max pooling layers are not used within any component of LatticeNet. Additionally, a convolution stack is usually only used in a feature extraction capacity, where the presence and strength of each feature within an input is indicated in the resulting feature maps. As a final component of a CNN, these feature maps are usually flattened and fed to a regression stack of densely connected layers which are responsible for regressing the flattened feature maps against the output vector.

LatticeNet. The basic components of LatticeNet are described above. This section is devoted to detailing the network architecture in terms of how different components are connected together and the allowed ranges for relevant hyperparameters associated with these components. The data decompositions described in the Convolutional Neural Networks Section are used directly in this description.

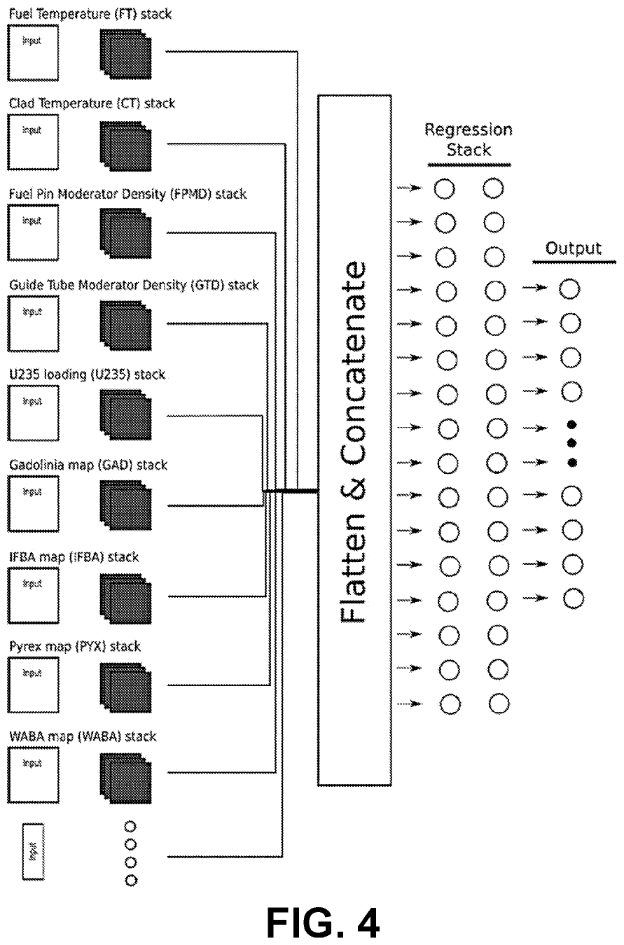

The first issue to be explored is how the differently decomposed input channels are to be fed into the network. An initial attempt might be to place all decomposed input channels into a single multi-channel image to be fed to a single convolutional stack, which is similar to the network shown in FIG. 3. There are two issues with this, however: (1) the control rod/boron concentration stack as described in the Convolutional Neural Networks Section is a one-dimensional vector of length two, and (2) the features described by the different information channels are very different and do not have a strong correlation or have no correlation with each other. The first issue can possibly be solved by expanding and reshaping the control rod/boron concentration input into two separate channels. However, the transformation of two scalar parameters to two separate 17×17 arrays would be massively redundant. The second issue is not as easy to resolve, as CNNs assume that a given feature will have some component in different channels of the same input image. This may be true for a few physically coupled variables such as fuel temperature and clad temperature. However, for design variables such as burnable poison placement and ²³⁵U concentration, there is no logical feature correlation between these two channels of data. To resolve both of these issues, LatticeNet explicitly separates each parameter channel and feeds these channels into separate feature extraction stacks. For channels that can be formatted into 2D data, such as fuel temperature and burnable poison placement, the feature extraction stack is composed of convolutional layers. For channels such as the control rod/boron concentration channel that are better expressed as scalar variables, the regression stack is instead a single densely connected layer. After these separate feature stacks are created, the individual flattened feature maps are then concatenated into a single vector of values which are then fed into a densely connected regression stack. LatticeNet is therefore a modular neural network, where individual subtasks are handled by separate network components (the fuel temperature stack, for example) which feed into the overall densely-connected stack which is responsible for handling the regression task. An overview of the general structure of LatticeNet is shown in FIG. 4. Note that the different regression stack sizes are not indicative of the final converged architecture.

Specialized restrictions that can be placed on the different feature extraction stacks are described next. Any network configuration details that are indicated as being allowed to vary are considered hyperparameters and were optimized via the hyperparameter optimization strategy discussed in the Hyperparameter Optimization Section. The first stacks described are the fuel temperature, clad temperature, and fuel pin moderator density stacks. The primary restriction placed on these stacks was that the output feature maps from each convolutional layer had to be the same shape as the input data (17×17); this implicitly assumes that interesting spatial data exists at all spatial locations in the input, including the edges. The kernel size was also restricted to a square kernel varying between either 2×2, 3×3, or 4×4 in size. The implicit assumption was that the neutronic effects of these thermal hydraulic parameters are highly local. Since there is no prior information on how many features are useful for neutronics parameter prediction, the number of filters was allowed to vary between 1 and 25 as a starting point. Finally, since there is also no prior information on which activation functions are the most useful, the activation function was allowed to vary between most of the common activation functions implemented in TensorFlow.

Next, the guide tube moderator density and ²³⁵U enrichment stacks enforce the restriction that the kernel size is 17×17. The implicit assumption here is that, since this stack's input will be composed mostly of zeros or uniform values, features that are interesting can be distinguished most efficiently by simply examining the entire assembly. Again, since there is no prior information on what the appropriate number of features or activations are, these hyperparameters are allowed to vary in the same ranges that the fuel temperature, clad temperature, and fuel pin moderator density stacks are allowed to vary. It is worth noting that since the kernel is 17×17, only one output is produced. Because it is difficult to perform subsequent convolutions on a single value, these stacks were restricted to being composed of only one layer.

The gadolinia, IFBA, Pyrex, and WABA stacks that each describe the presence or absence of a particular burnable poison are similarly restricted to a 17×17 kernel size, with the primary difference between these and other stacks being that the activation is also restricted to only the rectified linear unit (ReLU) activation function. This is due to the discretized nature of the burnable poison stacks, since they each describe only one burnable poison pin design and whetherit is present/absent in a given lattice location. As the ReLU function returns the maximum of either 0 or the input value, this activation should apply more readily than most other activation functions, which are usually intended for the non-linear transformation of floating-point values. Otherwise, again there is no prior information on the correct number of features to search for, so the number of filters is allowed to vary between 1-25, and the number of convolutional layers in the stack is restricted to one. The single-layer restrictions and 17×17 restrictions may not be optimal for the IFBA stack, since its input may not be sparse. IFBA pins were not placed with the same sparse restrictions as those imposed on the gadolinia, Pyrex and WABA pins. Therefore, it may be beneficial to use smaller kernel sizes and to use more layers in the stack. For the sake of simplicity, however, these details are not studied further in the initial version of LatticeNet.

The control rod position/boron concentration stack is assumed to only require a single-layer, small, densely connected network. The activation function was again allowed to vary between the most commonly available TensorFlow activations, while the layer size was allowed to only vary between 2-100 neurons.

Once the input is passed through all of the feature extraction stacks, the different feature maps are flattened and concatenated into one vector and fed to a regression stack composed of densely connected layers. The number of layers in this stack was varied from 0-2, with each layer's size allowed to vary between 2-1,000 neurons, and the activation function was also allowed to vary between most common TensorFlow activations, just as with the control rod position/boron concentration stack. This regression stack was connected to a final densely connected output layer composed of 289 neurons (in the case of regressing against pin powers) or 1 neuron (in the case of regressing against k_{eff}). In both cases, no activation function was used to introduce non-linearities in this output layer. For the pin power case, renormalization is appropriate but was not implemented in the neural network, as initial renormalization experiments seemed to only serve as a source of “confusion” for the neural networks when backpropagating error between the predicted and target values.

Hyperparameter Optimization. The basic architecture of LatticeNet has been defined. However, as described in the LatticeNet Section, all of the stacks possess independent hyperparameters that are set by the experimenter. There are three significant problems: unknown likely optima, high dimensionality, and significant computational requirements. The first problem is one of inexperience: for example, it is unknown for nuclear applications whether one set of hyperparameter values is preferable over another. The second problem builds on the first, in that as more layers are added to different feature extraction stacks, more and more hyperparameters appear for which the general optimal range is totally unknown. The third problem is a direct result of the first two: the training of hundreds or potentially thousands of different variants of LatticeNet quickly becomes computationally infeasible unless using high-performance computing resources. One way to search for hyperparameters might be to perform a grid search and then pick the set of hyperparameters with the lowest error. Since there is no prior information on what ranges of values are optimal, the problem of computational complexity caused by the first two issues makes this approach non-viable, as the hyperparameter space undergoes a combinatorial explosion in the number of possibilities. Additionally, it is known that a grid search is fundamentally the worst-case method of choosing hyperparameters in most scenarios with low effective dimensionality, and indeed, a random search is much more performant than a grid search in such scenarios. As it is unknown but certainly possible that the LatticeNet model may possess low effective dimensionality, this assertion is reasonable as a justification for avoiding using a grid search for finding LatticeNet's optimal hyperparameters.

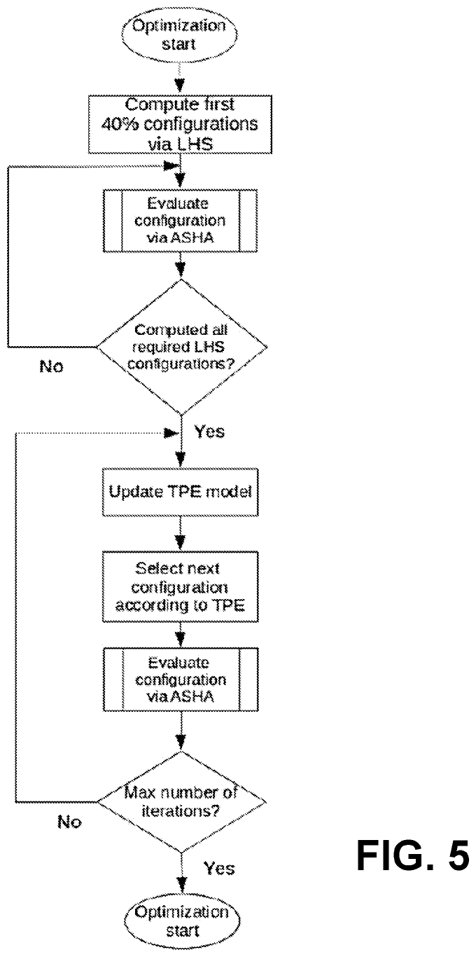

To effectively converge to good hyperparameter values for LatticeNet, a strategy is proposed to use stratified random sampling followed by a principled search based on Bayesian optimization. For the stratified sampling component, Latin hypercube sampling (LHS) was used since this method is guaranteed to cover all components of the hyperparameter optimization space. This was motivated by the subsequent use of the Bayesian optimization method, in this case the tree-structured Parzen estimators (TPE) algorithm. This robust hyperparameter optimization algorithm is capable of handling discrete and continuous hyperparameter values, and it is known to be performant for large and conditional search spaces. The algorithm forms an initial guess as to the distribution of the hyperparameter space, and updates this model as it suggests new hyperparameter sets, or trials, and received feedback on their performance. However, it is possible that this initial guess may be biased by the initial distribution's seed and may not lead to the best solution convergence. To resolve this, the LHS method is used to sample the first 40% of the total number of samples the strategy is allowed to try. The TPE algorithm is not allowed to select any points before these first population members are evaluated. Once these initial points are evaluated, the TPE algorithm updates its internal model based on the performance of these population members and then begins to suggest new sets of hyperparameters. This strategy resolves the first two issues by finding local optima independent of researcher knowledge, and it effectively handles the problem of high dimensionality. A diagram of the LHS/TPE search algorithm can be found in FIG. 5.

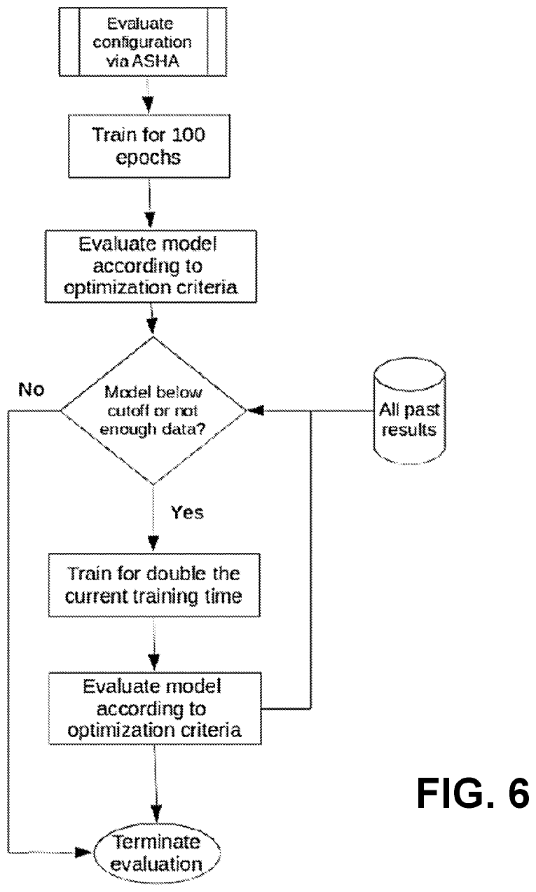

The LHS/TPE strategy outlined is sufficient to converge to effective hyperparameter values. However, the third issue still exists for cases in which a large number of population members (>100) is desired. To combat this, the proposed strategy adaptively prunes and stops the training of those hyperparameter sets suggested by the LHS/TPE methods. This was done using the asynchronous successive halving algorithm (ASHA), which stops the training of those trials that are not as performant as the fraction 1/η of trials that have already reached the same point or time step. Trials that are allowed to progress further are allowed to train for η*(current time step) additional time steps before being evaluated again, subject to the same cutoff criteria as before. In this way, models that are performant relative to their peers are allowed to continue, while those that underperform relative to their peers are stopped in favor of allowing new trials to be evaluated. Note that in this case, a time step is actually defined as 100 training epochs. A diagram of the ASHA adaptive pruning method can be seen in FIG. 6.

### Results & Discussion

The TensorFlow platform was used to implement and train LatticeNet, as it allows for easy implementation and exploration of novel architectures. The Adam optimizer was used with the AMSGRAD correction, as Adam has been found to generally be the most performant in hyperparameter search problems with respect to other neural network optimizers, especially when there is a limited computational budget. It was also found to be the most performant for this specific problem in initial exploratory studies not shown here.

All models and experiments were implemented and performed on an NVIDIA DGX Station, which contains four Tesla V100 GPUs. For this research, the full LHS/TPE-ASHA strategy was implemented in Ray Tune, an open-source hyperparameter optimization platform. The strategy was used with an η value of 2 (50% pruning at every checkpoint) and was allowed to train individual models for up to 50 time steps (5,000 epochs). These settings were chosen primarily for computational convenience, as the completion of a full run with these settings could usually be accomplished overnight on the DGX workstation.

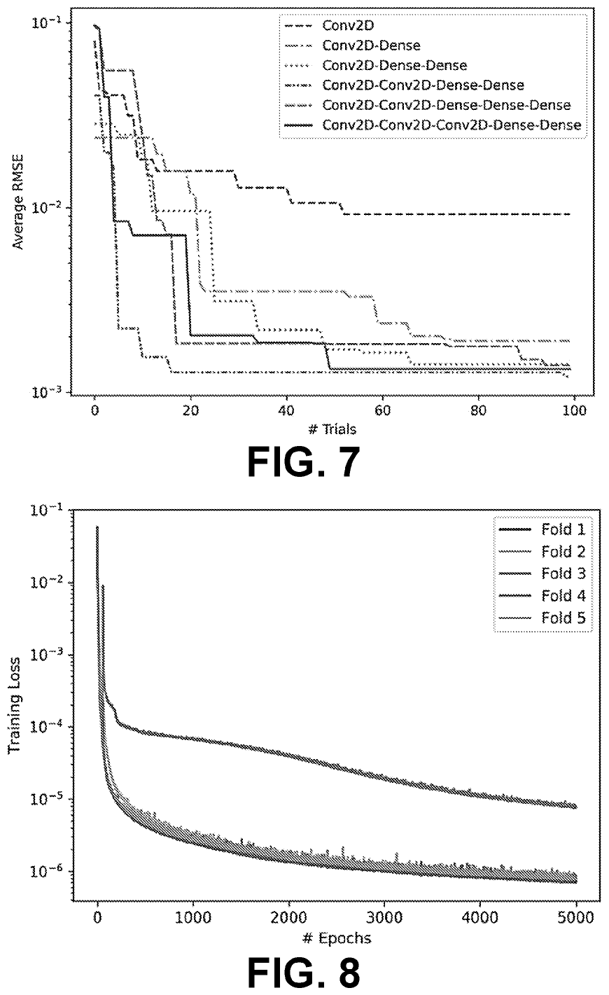

Normalized Pin Powers. An analysis of the best-performing LatticeNet variants was conducted using the LHS/TPE-ASHA strategy with a limited number of trials (100 total, 40 from LHS), obeying the pre-sampling strategy outlined in the Hyperparameter Optimization Section. Five different configurations were examined: LatticeNet with zero, one or two layers in the regression stack, and LatticeNet using one, two or three layers in those feature extraction stacks not limited to one layer, with the regression stack held constant at two layers. In all cases, the dataset was randomly shuffled and divided in a 60-20-20 manner, where 60% of the data was used to train the network, 20% was used by the LHS/TPE-ASHA strategy to optimize hyperparameters, and 20% was used as a holdout testing set not given in the training or testing data to provide an unbiased evaluation of network performance. The results of this comparison can be found in FIG. 7.

FIG. 7 shows that LatticeNet with no layers in the regression stack (flattened features are fed directly to the final output layer) was not nearly as performant as variants with at least one layer. Two layers in the regression stack appear to achieve the best performance (different experiments not shown here corroborated this), so the regression stack was frozen in this analysis at two layers. Subsequent experiments added in more layers to the fuel temperature, clad temperature, and fuel pin moderator density; this appeared to correlate with reduced error, although this may not always be the case due to the marginally better error of the Conv2D-Conv2D-Dense-Dense architecture compared to the Conv2D-Conv2D-Conv2D-Dense-Dense architecture.

While it may be informative to perform an initial survey of best architectures using a small number of trials, it is worth noting that this population size may become unsatisfactory as more layers are added to the feature extraction stacks. This is due to the increasing number of hyperparameters introduced by each layer; the Conv2D-Conv2D-Conv2D-Dense-Dense architecture, for example, possesses 42 separate hyperparameters. For this large search space, 100 trials with 40% stratified random initial points may be too few trials to effectively converge to good hyperparameters. To resolve this, the three best-performing LatticeNet variants shown in FIG. 7 were allowed to again be optimized via the LHS/TPE-ASHA strategy, this time allowing 500 trials in total (200 trials from LHS). The performance of the top ten models from these optimization runs are shown in Table III.

TABLE III
Comparison of samplewise RMSE statistics
for each LatticeNet variant studied.

| | Average RMSE |
|---|---|
| Conv2D-Dense-Dense | (1.269 ± 0.051) × 10⁻³ |
| Conv2D-Conv2D-Dense-Dense | (1.046 ± 0.029) × 10⁻³ |
| Conv2D-Conv2D-Conv2D-Dense-Dense | (0.971 ± 0.017) × 10⁻³ |

As can be seen in Table III, when allowed more trials to optimize, there was a clear trend in which increasing the number of layers in the fuel temperature, clad temperature, and fuel pin moderator density stacks directly resulted in a lower average RMSE amongst the top-performing models. It is notable that the standard deviation of the RMSE values also decreased in proportionality to the average RMSE, from 4% down to 1.7%. This may suggest that even with an increasing number of hyperparameters, optimal values are easier to converge to with increasing layers. Alternatively, it could indicate that additional layers might allow for corrections to mistakes introduced by earlier layers in the stacks.

Next, the best-performing hyperparameter set for the best-performing LatticeNet variant (Conv2D-Conv2D-Conv2D-Dense-Dense) used k-fold cross-validation to train multiple models using these hyperparameters, with k=5. The average RMSEs and standard deviations from the different folds are shown in Table IV. Note that for the first three columns, statistics were performed in a samplewise manner in which the RMSE was calculated for each set of input-output pairs independently, and the average or maximum was then taken across the resulting vector of values. As the average RMSEs from most of the different folds match closely with those shown in Table III, it can be concluded that the produced LatticeNet model may be robust to scenarios inside of its training domain.

TABLE IV
Performance on the testing datasets for all five
folds of the best-performing LatticeNet model.

| | | | Avg. Max | Max |
|---|---|---|---|---|
| | | | Absolute | Absolute |
| | Avg. RMSE | Max RMSE | Error | Error |
| Fold 1: | 8.28E−04 ± 3.85E−04 | 3.46E−03 | 3.03E−03 | 1.82E−02 |
| Fold 2: | 8.87E−04 ± 4.04E−04 | 2.78E−03 | 3.26E−03 | 2.53E−02 |
| Fold 3: | 7.80E−03 ± 9.27E−03 | 8.28E−02 | 2.20E−02 | 2.19E−01 |
| Fold 4: | 9.20E−04 ± 3.54E−04 | 2.49E−03 | 3.24E−03 | 1.67E−02 |
| Fold 5: | 8.76E−04 ± 3.85E−04 | 3.33E−03 | 3.17E−03 | 1.95E−02 |

One anomaly is exhibited in Table IV in Fold 3, where all error statistics are significantly greater than the other folds. This behavior was not consistent across multiple repeated trials using the same random seed for cross validation, with different trial runs randomly producing significantly higher errors in one or more folds, and some producing no errors in any folds. A plot of the training loss for the different folds from Table IV is shown in FIG. 8 (the y-scale is logarithmic). As can be seen, the training loss appears to spike at a small number of epochs (less than 1,000 was observed consistently) before descending at a rate mostly consistent with the rate of descent of the other folds, although at a significantly increased offset compared to the others. A curve very similar to that shown by Fold 3 was consistently seen in other trials in which the error was randomly much worse than expected in one or more folds, where the training loss (the average loss of the model computed on the training portion of the dataset) was seen to spike and then descend as normal for the suspect folds. Given this behavior, it is possible that this is due to the stochastic nature of neural networks in which the neuron weights are randomly initialized upon network creation and are not consistently kept the same between trial runs or even between folds. There may be a family of weight initialization values that cause the network to settle in an alternate domain which was locally optimal but perhaps far from the best local or global optima. This brittleness is an issue, but the authors do not believe it completely disproves the viability of the approach as, on average, most folds appeared to avoid these bad local optima.

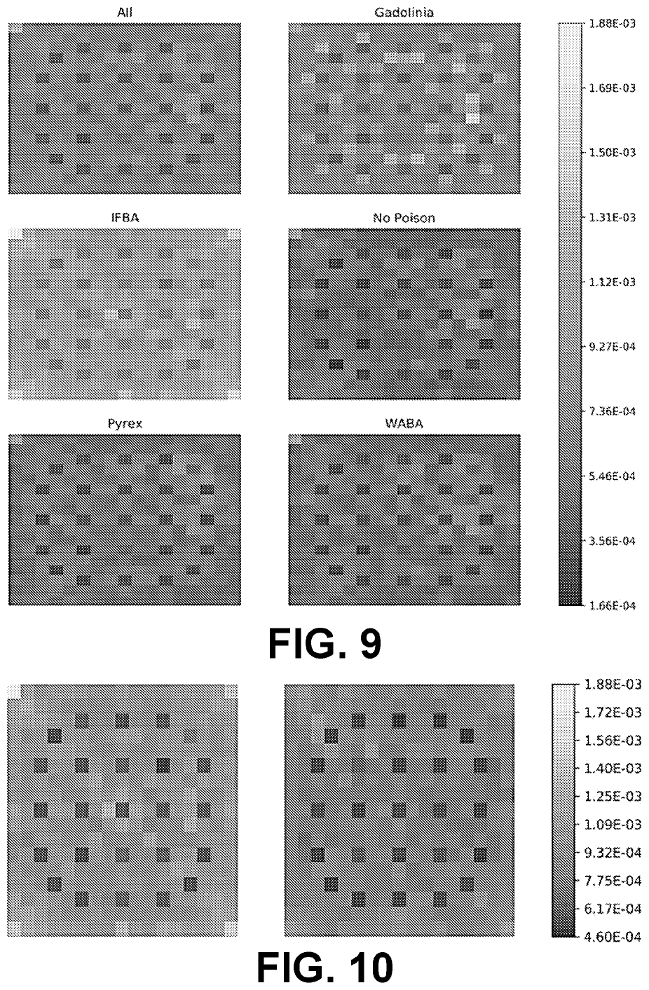

The performance of the produced model can be analyzed further by examining the pinwise error of the model produced by the best-performing fold (Fold 1) in Table IV. Plots of the pinwise average absolute error across all samples in the test dataset (the “All” fuel group), as well as across the different fuel groups, can be found in FIG. 9. FIG. 9. illustrates average pinwise absolute error for all samples and for each specific fuel group; MPACT-computed pin powers were used as reference. All color values were normalized to the same color map. As can be seen, the majority of the error across all fuel groups is below 10⁻³ on average. There are a few interesting features presented in the fuel group—specific plots, however. In the gadolinia plot, for example, the error appears to be distributed nearly symmetrically, and in fact appears to be concentrated in and around those pin locations described as gadolinia-bearing in six designs given by Godfrey and Blair. Of particular note is the “four corners” behavior in the error plot, where the error is seen to be the highest in a “crown” around the corner guide tubes, directly correlating with those fuel pins containing gadolinia in the 24-pin and 16-pin gadolinium loading patterns. This may indicate that the network is performant enough to capture the inherent computational challenge that is known to be associated with gadolinia as a burnable poison.

The other interesting component is the pinwise error that was produced by the IFBA fuel group, which appears to have produced the highest error amongst all of the burnable poison groups. A possible explanation for this worst-case performance (as nearly all fuel pins appear to be uniformly bad) may be due to the initial restrictions placed upon LatticeNet. The IFBA feature extraction stack, like the other burnable poison “presence” feature extraction stacks, was restricted to a 17×17 kernel size, and the only hyperparameter allowed to vary for this stack was the number of unique 17×17 features that were allowed to be searched for, from 1-25 filters. This initial formulation may be too simple, however; unlike the gadolinia, Pyrex or WABA burnable poison groups, a given IFBA presence map may not be sparse since IFBA placement is not restricted to certain guide tube/fuel pin locations. It is also possible that with this large kernel size, the nature of IFBA placement may produce some so-called confusion in the network insofar as multiple filters may match closely but not exactly with the burnable poison placement pattern. It is possible then that the regression stack may receive multiple close matches for different IFBA configurations, causing it to be unable to extract the exact spatial IFBA configuration and thus being unable to establish a relationship between a given IFBA configuration and local features of the pin power. Additionally, even if the 17×17 kernel size is nota source of confusion and the number of filters allowed is the only issue, then blindly adding more filters may not be a reasonable approach. If there is a strong correlation between the IFBA error and the number of filters used, then logically this means that the model will always be restricted in the IFBA designs it can successfully predict by the number of filters it possesses and whether it has been trained on that specific IFBA design.

To resolve the issue of IFBA's under-performance, the kernel size of the IFBA feature stack was allowed to vary between 2×2, 3×3, and 4×4, and the hyperparameter optimization strategy was re-run with this new allowed variation. A comparison between the error in the IFBA group from FIG. 9 and the error produced by the best-performing fold using the re-engineered IFBA feature extraction stack can be found in FIG. 10. FIG. 10. Shows a comparison of the average pinwise absolute error produced by the IFBA fuel group for the initial version of LatticeNet (17 17 kernel size) and the updated version of LatticeNet, which allowed variation of the kernel size. All color values have been normalized to the same color map. As can be seen, the error for the IFBA fuel group was generally suppressed from that produced by LatticeNet when the kernel was restricted to 17×17, although the error was still not as low as that produced by the Pyrex and WABA groups. A possible cause of this may be due to the IFBA fuel group in particular possessing too many IFBA pins, similar to the effect discussed when allowing gadolinia pins to be freely placed. The number of allowed IFBA fuel pins may be restricted in a manner similar to the measures taken to restrict the gadolinia pins.

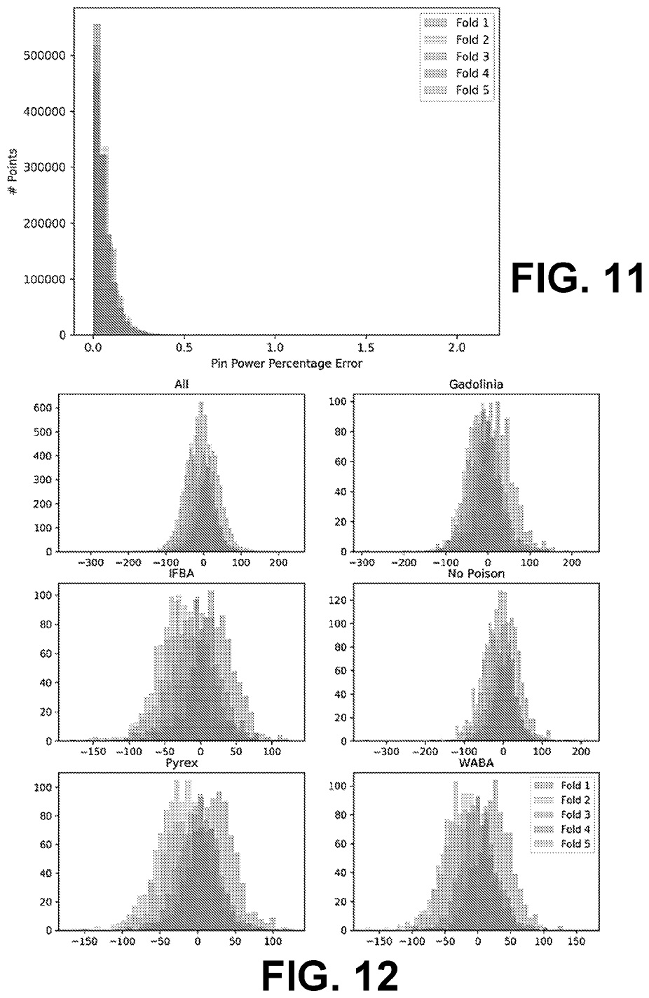

The final converged LatticeNet model for pin power prediction possessed an average pin power percentage difference of 0.05% and a maximum pin power percentage difference of 1.8% for the best-performing fold. A distribution plot of all pin power percentage difference values is shown in FIG. 11 (outliers are included (although not visible), causing a large skewing of the y-axis), where the maximum error across all folds is approximately 2.5%. As can be seen, for the majority of points, the predicted error is competitive with the maximum error produced when comparing the high-fidelity codes MPACT vs. Serpent (0.5% for MPACT), with the maximum error from the neural network predictions slightly worse than the maximum error between Simulate-5 and CASMO-5 (2%). These errors, and specifically the outlier shown in FIG. 11, show that the model is not ideal for applications in which guaranteed accuracy is desired; however, for scenarios that do not require a guarantee of accuracy these, models may serve as acceptable alternatives, especially given their computational benefits (described further in the LatticeNet vs. Nodal Methods Section).

Criticality Eigenvalue Prediction. The LHS/TPE-ASHA algorithm was re-run on the general LatticeNet architecture converged to in the Normalized Pin Powers Section, this time optimizing for the problem of regressing against k_{eff}. Incorporating the lessons learned from regressing against pin powers, the IFBA feature stack was again allowed to vary the kernel size between 2×2, 3×3, and 4×4, as well as the number of filters. The error statistics from 5-fold cross validation performed on the best achieved model are shown in Table V, and distribution plots of the k_{eff} error in pcm are shown in FIG. 12. FIG. 12. Shows the distribution plots of the error in pcm between the actual and predicted k_{eff} values for the different fuel groups from the best-performing LatticeNet model. All five folds are shown in these density plots. As can be seen, the maximum error was less than 400 pcm, with the majority of the error distributed between −200 and 200 pcm for the gadolinia, IFBA, and No Poison groups, and −150 and 150 pcm for the Pyrex and WABA fuel groups.

TABLE V
Performance of the testing sets for all five folds
of the best-performing LatticeNet model.

| | Avg. absolute error | Max absolute error |
|---|---|---|
| Fold 1 | 2.41E−04 ± 2.14E−04 | 3.55E−03 |
| Fold 2 | 3.18E−04 ± 2.71E−04 | 2.93E−03 |
| Fold 3 | 2.33E−04 ± 2.03E−04 | 1.85E−03 |
| Fold 4 | 3.18E−04 ± 2.49E−04 | 2.38E−03 |
| Fold 5 | 3.78E−04 ± 2.55E−04 | 1.83E−03 |

One interesting feature of FIG. 12 is that the distributions appear to be mostly zero-centered, with some folds centered around points in the neighborhood of ±50 pcm from zero. The position of these off-center distributions does seem to be correlated to specific folds for specific fuel groups. The off-center bias in the Pyrex and WABA groups shows up particularly strongly. It is possible that these off-center distributions are due to the random neuron weight initialization, similar to the effect driving the loss spike shown in FIG. 8. Work is ongoing to try and resolve these off-center issues, although the authors do not think it has a strong negative effect on the quality of the results, as the displacements are small, and the distribution curves appear to maintain their overall shape.

The final converged LatticeNet model for k_{eff} prediction, as can be seen in FIG. 12, produced an error of less than 200 pcm from the MPACT-computed reference solutions in the majority of cases, although there was a small number of samples with pcm errors above 200 in some fuel groups. Given that LatticeNet produced a maximum pcm difference of approximately −355 pcm and that high-fidelity codes generally make predictions within 100 pcm of reference values, this figure clearly shows again that LatticeNet is not viable for calculations that require a guarantee of accuracy. However, for applications in which a computationally cheap estimate of k_{eff} may be desired, the use of LatticeNet may be viable for a “good first guess.”

LatticeNet vs. Nodal Methods. To compare the prediction error of LatticeNet with the error of other similarly cheap nodal methods, the CASMO-4E/SIMULATE-3 code suite was used to perform the two-step procedure commonly used in LWR core design calculations. A 2D PWR assembly was constructed in CASMO-4E corresponding to the assembly geometry and material specifications given in Problem 2 of the VERA Core Physics Benchmark Progression Problems. In this way, the problem geometry used by CASMO-4E/SIMULATE-3 and by MPACT/LatticeNet is effectively one-to-one, barring minor composition and implementation details specific to each code. A set of 1,000 unique fuel temperature distributions (separate from the training/validation/testing data described and used earlier) was then created and imposed on both MPACT and CASMO. All other thermal hydraulic and design parameters were held constant, allowing the study of the error introduced by the nodal method specifically w.r.t. fuel temperature, independent of other variables such as boron concentration or fuel enrichment. Table VI shows the steady-state values that all other assembly design parameters were held at, as well as the range over which the fuel temperature distributions were allowed to vary. Design parameters not mentioned explicitly were set equal to those given by Godfrey.

TABLE VI
Value of all relevant assembly design parameters
replicated in CASMO-4E and MPACT.

| Design Parameter | Value Range | |
|---|---|---|
| Fuel Temperature | 600-1400 | K |
| Clad Temperature | 565 | K |
| Moderator Temperature | 565 | K |
| Lattice Enrichment | 3.1% | |
| Boron Concentration | 700 | ppm |

| | |
|---|---|
| Control Rod Position | Withdrawn |

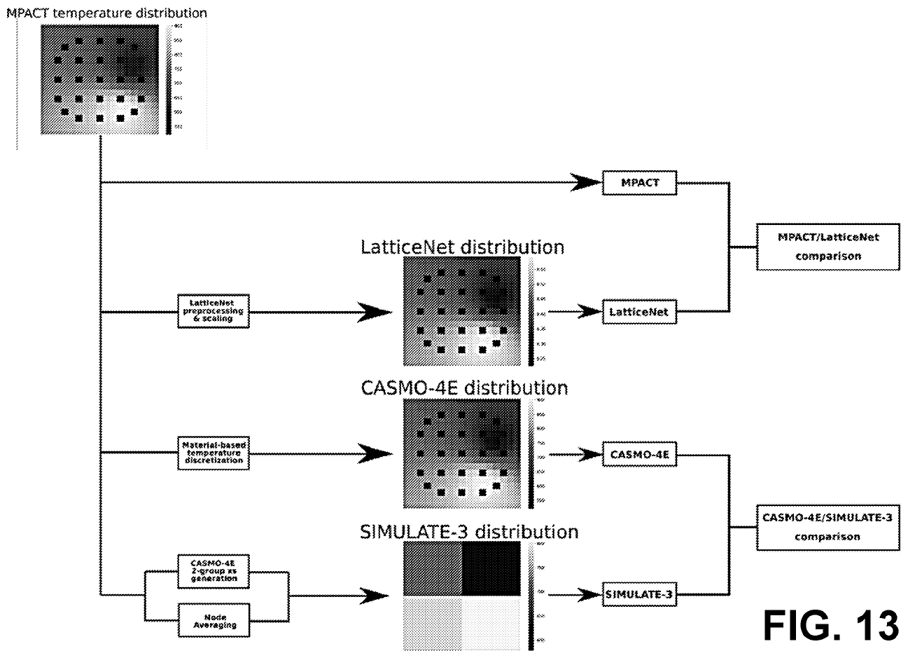

The generated fuel temperature distributions can be passed directly into MPACT, using the User Defined TH capabilities of MPACT. Since LatticeNet was trained using the same data fed into MPACT, it is straightforward to get an“answer” from LatticeNet, as the geometry/material information and temperature distribution can be fed directly into the network after they are appropriately scaled. CASMO-4E does not possess these same capabilities, and ties fuel temperature to specific material compositions. To get around this limitation, 60 linearly-spaced bins were used to discretize over the upper and lower limits of each temperature distribution independently, where a unique fuel composition was assigned per-bin and each pin cell was assigned the material which was closest to the corresponding temperature in the MPACT distributions. In this way, the temperature distributions simulated in MPACT were roughly approximated in CASMO-4E. To mirror these distributions in SIMULATE-3, statepoints were generated in CASMO-4E which spanned the entire theoretical range of the temperature distribution (600K to 1400K) in 50-degree increments, with these statepoints included in the post-processed two-group library produced by the linking code CMSLINK. To actually model the irregular temperature distributions, a 2×2 node mesh was used to represent the single assembly in SIMULATE-3, with the assembly modeled as asymmetric to assure that each node used independent fuel temperature fits. Each node was then assigned their node-averaged fuel temperature computed from the corresponding temperature distribution run through CASMO-4E. An example of the temperature scaling (in the case of LatticeNet), temperature discretization (in the case of CASMO) and nodalization (in the case of SIMULATE-3) is shown in FIG. 13. FIG. 13. Shows an overview diagram showing the different stages of processing the temperature distributions used to generate this comparison went through before being passed to their corresponding codes. It also shows exactly how the comparisons in this section were performed, where SIMULATE-3 results were compared using CASMO-4E as the reference and LatticeNet results were compared to MPACT as the reference.

A plot of the average absolute percentage error is shown in FIG. 14. FIG. 14 illustrates a plot of pin power errors between MPACT/LatticeNet and CASMO-4E/SIMULATE-3. CASMO-4E results were used as the reference values for corresponding SIMULATE-3 results, and MPACT results were used as the reference for the corresponding LatticeNet results. In this case, the error being computed is the difference between CASMO-4E/SIMULATE-3 or MPACT/LatticeNet. There is no comparison of errors shown between CASMO-4E/MPACT, as the point is to show the error achievable by their approximate models (SIMULATE-3 and LatticeNet) and not to compare the accuracy of these codes with each other. The average error produced by the SIMULATE-3 code (w.r.t. the CASMO-4E solutions) across all samples is approximately 0.1%, with a maximum pinwise error of 1.3%. These value fall within the ranges indicated by Bahadir et. al (1-2% indicated for some assemblies). By comparison, the LatticeNet model (w.r.t. MPACT) produced an average error of 0.02%, with a maximum pin-wise error of 0.24%. These errors are well within those expected of LatticeNet, considering that the test scenario contains temperature distribution ranges that are well within the training regions given to the network, with no additional complexity included such as the placement of burnable poisons. Overall, LatticeNet clearly produces a better prediction of the pin-wise powers for almost every distribution given. This is again expected, as LatticeNet is effectively being trained to mimic MPACT, while SIMULATE-3 is restricted to much more coarse homogenized data.

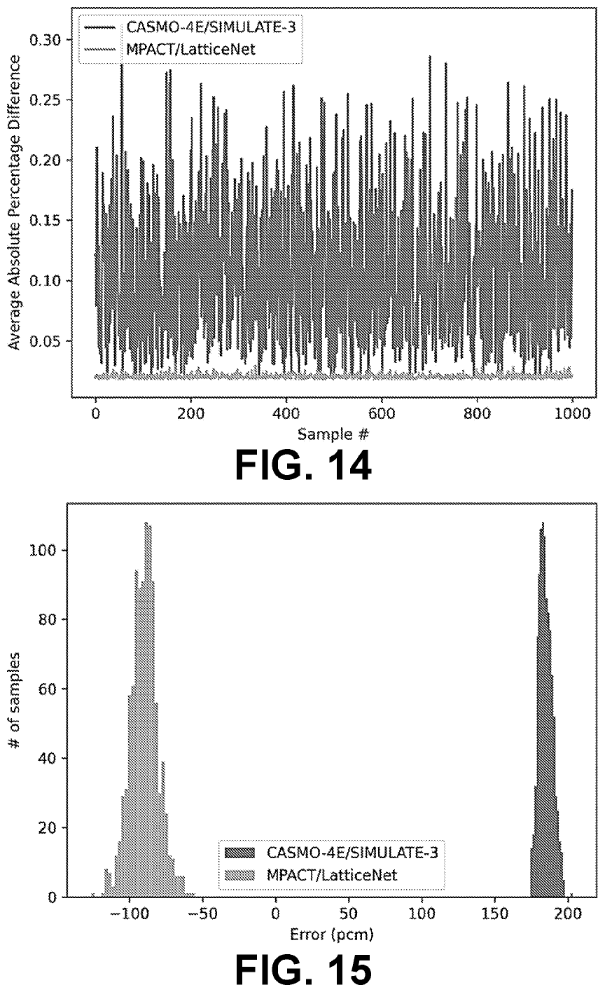

A distribution plot of the k eff prediction error in pcm between the CASMO-4E/SIMULATE-3 codes and MPACT/LatticeNet is shown in FIG. 15. FIG. 15 shows a plot of k_{eff} errors in pcm between MPACT/LatticeNet and CASMO-4E/SIMULATE-3. CASMO-4E results were used as the reference values for corresponding SIMULATE-3 results, and MPACT results were used as the reference for the corresponding LatticeNet results. As can be seen, the difference between CASMO-4E and SIMULATE-3 is on average 180 pcm, with minimum and maximum differences of 174 and 203 pcm, respectively. By comparison, the LatticeNet model produced an average error of −90 pcm, with minimum and maximum differences of −55 and −124 pcm, respectively. These differences are again within reasonable expectations, although it is interesting that SIMULATE-3 and LatticeNet are roughly centered around positive or negative values, respectively, and that both appear to be distinctly separated from each other with zero overlap in the distribution of errors between the two. Overall, LatticeNet does appear to be slightly more accurate, although not significantly better when compared to SIMULATE-3.

Speaking to the computational performance of nodal methods, we can make a direct comparison between the number of lattice cases needed to “run” the neutronics models with the errors indicated by FIG. 14. To generate a single element in the case matrix used by SIMULATE-3, CASMO-4E took approximately 0.25 seconds on a 2.0 GHz machine; SIMULATE-3 took on average 4 seconds to run all 1,000 nodal solves using this case matrix. To duplicate the range of parameters present in the LatticeNet training data, a large number of additional branching calculations would be necessary to duplicate the allowed changes in lattice enrichment, boron concentration, fuel temperature, control rod presence and burnable poison content. Functionalizing these parameters on 10, 10, 10, 2 and 40 (10 burnable poison loadings per burnable poison group, excepting the No Poison group) branches respectively, a total of 100,000 CASMO-4E lattice calculations would be required to span the range of values over which the dataset was allowed to vary. Assuming the same average computation times from earlier, this dataset would take 7 hours to generate using a single core; SIMULATE-3 would then be able to compute the nodal solution for all 20,250 relevant statepoints in approximately one minute.

By comparison, MPACT was recorded as taking approximately 36 seconds for a single statepoint calculation on a single core, with all 20,250 statepoints used in the training of LatticeNet requiring just under six hours to fully generate using a 36-core machine. The total time taken to optimize LatticeNet using the TPE/ASHA algorithm, as well as the time required to perform k-fold cross validation and train a final model, took approximately 22 hours using an NVIDIA DGX-1 with 4 Tesla V100 GPUs; the final version of LatticeNet was then able to compute predictions on all 20,250 statepoints in approximately 36 seconds on a single core. It's worth noting that for the specialized case on which the comparison to CASMO-4E/SIMULATE-3 is based off of, where only the fuel temperature distribution is changing, much of LatticeNet is not necessary. If we were to attempt to generate a version of LatticeNet which only handles fuel temperature distribution changes, all other assembly parameters being constant, no stack other than the Fuel Temperature stack in FIG. 4 would be required. This would undoubtedly speed up the inference time of the network, and would also mean far less training data and training time would be required to produce a model with equivalent or better error values.

This work introduces LatticeNet, a neural network architecture based on computer vision and modular neural network approaches that takes lattice information decomposed into an image-like format and uses this information to predict either the normalized pin powers or the assembly k_{eff}. A methodology for designing and optimizing the hyperparameters of this network is introduced that uses stratified random sampling and probabilistic search to effectively find good sets of hyperparameters for a given regression task. It is demonstrated that LatticeNet, when tuned using this methodology, can effectively predict the normalized pin powers with less than 0.005 absolute error per-pin in most cases, even when including common burnable poison types. For these same burnable poison groups, it is shown herein that LatticeNet can also be trained and tuned to predict k eff to within 200 pcm in most cases. Assemblies that contain IFBA and gadolinia burnable poisons appear to be the most challenging configurations for the network to regress against; they require further work to reduce the prediction error to the same level as that produced by the Pyrex, WABA, and No Poison burnable poison groups.

From the computational analysis it can be seen that LatticeNet—and by extension, almost all neural network models—involves a significant up-front cost in terms of data generation, network design and network training. The primary benefits of using neural network-based methods exist in their prediction time, their ability to capture high-fidelity features, and their ability to be informed by high-fidelity codes nearly autonomously. As has been shown, even a computationally complex network such as LatticeNet (which contains nearly 14 million independent weights) was able to run in approximately half the time that the nodal solve was able to run in. Unlike nodal solutions, LatticeNet is not bounded to a homogenized representation of the assembly data, and is thusly able to compute fine parameter distributions without the need for analytically-derived expansion methods such as pin power reconstruction. To generate an appropriate neural network model, then, one needs only a high-fidelity code which is known to be correct in the physics domain of interest; analytical or empirical methods similar to the two-step procedure are not needed, and so researcher time and effort is saved at least initially. This carries interesting implications even for modeling & simulation of non-light water reactors, although application to those domains is certainly one that would require more work to prove.

While this work has focused on the most interesting aspects of LatticeNet, there are still several areas in which the architecture may be explored and improved further. For example, there appears to be a direct correlation with the depth of the thermal hydraulic feature extraction stacks and LatticeNet performance; which may provide a benefit by making these stacks arbitrarily large. The dataset used in this research was also limited in that it only considered one pin design for each burnable poison type; expansion of the dataset to include variations on these designs may prompt extensions or redesigns of those feature extension stacks responsible for extracting burnable poison features, similar to what was done to accommodate the IFBA burnable poison group. Finally, optimizations and scaled-down variants of the LatticeNet architecture may be possible; it may be possible to reduce the number of needed feature stacks for burnable poisons by combining different features, although whether these combinations will have an effect on accuracy, and by how much, is unclear. The work shown in this paper has been a proof-of-concept showing the capabilities of LatticeNet.

The authors believe that there are promising applications for neural networks in neutronics, if for no other reason than the speed of solution and ease of configuration afforded by their use. The pinwise error comparison in the LatticeNet vs. Nodal Methods Section shows that LatticeNet is able to emulate MPACT well enough to perform at an equivalent level or better to nodal methods in terms of predicting parameter distributions from pin-wise changes. The computational comparison in the same section also shows that LatticeNet is able to do this approximately half of the time required by nodal methods, even for versions of LatticeNet which contain more components than what is strictly necessary. Therefore, the data-driven model—LatticeNet, in this case—is able to combine the accuracy strengths of a high-fidelity solver (MPACT) with the computational strengths of low-fidelity nodal methods. The primary benefit that both of these methods have, which LatticeNet does not, is explainability; as far as the authors are aware, there are no techniques for decoding “why” a neural network gives the answer it does. Current machine learning research is unequivocal in the assertion that any data-driven model has no knowledge of the underlying physics it is attempting to approximate, and so can make no guarantees of correctness, which is important for nuclear applications. Therefore, the authors believe that for applications in which accuracy is not as important as speed, far away from important final calculations, neural network-based models may serve as a computationally expedient tool for preliminary experiments. As an example, licensing calculations and final benchmarking calculations are not scenarios where these models would be used; however, they may be useful in exploratory experiments leading up to those final calculations, in which the correctness of the path taken to get to a converged solution or design is not necessarily as important as assuring that the final answer is correct.

Current machine learning research is unequivocal in the assertion that any data-driven model has no knowledge of the underlying physics it is attempting to approximate, and so can make no guarantees of correctness, which is important for nuclear applications. The central idea is instead that the computationally cheap nature of these models, as well as their ability to efficiently leverage the compute power of advanced HPC resources, may allow for the use of hybrid methods that combine regular high- and low-fidelity methods with data-driven models. While the authors are not certain exactly what the final form of such hybridized methods would be, the point is that these models would under no circumstance be used as a wholesale replacement of existing methods and would instead merely serve as a useful tool for scenarios in which speed and “more or less correct” values are preferable over guaranteed accuracy.

Next, we address the problem of scaling LatticeNet up to larger problem sizes. We examine this problem in the context of error, analyzing how different statistical measures of deviation from ground truth trend as we go to larger region sizes, and in the context of resources used, analyzing the compute expense across different region sizes. The datasets used in exploring these scaling issues will be described, providing some reasoning on the structure of the datasets, and describe the procedures used to explore the problem space. The original LatticeNet architecture will be examined and the theoretical scaling of the architecture to larger problem sizes analyzed, showing that the number of parameters involved scales unreasonably to problem sizes of interest such as full-core scenarios. Several variants of LatticeNet are proposed which reduce the scaling compute needs relative to the original proposed architecture. The performance of the proposed LatticeNet variants are compared, and the scaling behavior of these variants extrapolated to larger problem sizes.

### Datasets

To study region scaling behavior in multi-assembly regions, four different datasets were generated corresponding to different region sizes. Each region is square and contains R×R separate assemblies, where R is the number of assemblies per side of a given region. For each dataset, 10,000 different square R×R regions were generated. For each region in all datasets, the fuel temperature, clad temperature and moderator density were all allowed to vary as randomly generated continuous curves. The purpose of this methodology was to generate smoothly-varying change curves in the data which the models can ideally learn relationships from, vs. randomly-varying noise of each pin location had its associated thermal hydraulic values selected separately. Each individual assembly was allowed to take on a random fuel enrichment between 1.8% and 4.9%. This enrichment was used for all fuel pins within a single assembly. The soluble boron concentration was allowed to vary between 0 and 2,000 ppm. Table VII summarizes the design variations allowed in these datasets. All data was generated using MPACT, a high-fidelity physics solver for neutron transport, where the randomly generated fuel material descriptions and thermal hydraulics curves were fed in as inputs to MPACT and the output of normalized pin powers were collected. It should be emphasized that, while MPACT (as part of the VERA simulation suite) has the capability to iterate with a coupled thermal hydraulics solver to come to a steady-state reactor solution, this capability was not used in this paper; only the specific neutronics capabilities of MPACT were used. Effectively, the goal of this paper is to describe the development of a neural network-based “replacement” for a very limited subset of the capabilities of MPACT, although this paper only describes a novel method for doing so and does not attempt to explore the implications on wider modeling & simulation capabilities.

TABLE VII
Summary of variations across all datasets within Scaling dataset.

| Design parameter | Allowed Range |
|---|---|
| Fuel temperature (Celsius) | 286-1,326 |
| Cladding temperature (Celsius) | 286-356 |
| Moderator density (g/cc) | 0.660-0.743 |
| Guide tube density (g/cc) | 0.660-0.743 |
| Fuel Enrichment | 1.8%-4.9% |
| Boron Concentration (ppm) | 0-2,000 |

In LatticeNet above various burnable poisons, as well as control rods, were included within the study. Burnable poisons and control rods were not used in this study due to the fact that including burnable poisons may inherently introduce a “placement problem”, where if a given assembly design containing a burnable poison is allowed to be placed freely then every assembly location should logically have at least one example containing that burnable poison within the training dataset. Without ensuring this, it is very feasible that the neurons connected to a specific assembly position will never be activated or trained, and if a burnable poison is placed into this untrained position at test time the evaluation of the test error may be unfair to the model. Attempting to accommodate all burnable poisons at all positions within the datasets therefore is likely to result in a “combinatorial explosion” in the amount of data that would need to be generated, especially when considering assemblies which use the same burnable poison content but with perhaps a different pin configuration. The previous study did not have to deal with this placement problem since the burnable poison content of each pin was explicitly represented (even if zero), and thus there would likely not be a strong loss of information if one pin in particular was not covered in the training data. This is because the kernel dimensions used were several pins wide and moved across the entire assembly in the previous study, and it would therefore be unlikely that the system would encounter scenarios where a parameter is left completely untrained. However, since this work deals with architectures that homogenize information at the level of entire assemblies (see the LatticeNet 1.3 Section) and do not permit kernel overlap, the placement problem becomes very relevant since there is no neighboring information and there is a real danger that some assembly positions will be left completely un-activated. Since this study is focused on addressing the much more immediate problem of architecture scaling, it was decided to ignore the inclusion of burnable poisons, however work is ongoing to address this issue.

### Analysis

We first analyze the general components of LatticeNet, and extract relevant statements on the number of parameters involved. We do not go into detail on these components or on the training/structure of neural networks, since implementation details specific to LatticeNet have been explained in the original paper describing LatticeNet and detailed information on neural networks is widely available. Thus, for the sake of brevity, we assume at least general understanding of neural network methods, concepts and implementation, and only describe fully-connected/convolutional networks and their associated input/output needs at a high level in the Neural Networks Section as these details are relevant to the analysis.

Neural Networks. In neural networks “learnable” (or “trainable”) parameters are parameters within the network which must be tracked and updated when training the network. The number of learnable parameters within a network has a direct effect on computation time and load, since chains of equations must be followed in order to update each parameter and there may be millions of parameters in a given model. Since the training process for a network is composed of iteratively updating each of these parameters in response to error on the training data, the number of learnable parameters is generally used as a simple metric to estimate how expensive a given model will be to train. While neural networks are stochastic machines, they are made up of individual sub-components or layers which follow sets of simple equations describing the number of learnable parameters introduced by each. Therefore, considering how changes in the input and output dimensions of certain layers affects the number of learnable parameters introduced at any stage, and what downstream effects this may have, is worthwhile to examine.

Fully Connected Networks. A fully-connected layer or densely-connected layer, takes a one-dimensional vector of values as input and outputs another one-dimensional vector, where each term within the output vector is the result of a linear transformation and summation of the input vector followed by a (possibly) non-linear transformation. Therefore, the number of parameters P^{F} introduced by a fully-connected layer goes as:

P^{F}=Nᵢ^{F}Nₒ^{F}+Nₒ^{F} (1)

where Nᵢ^{F} is the size of the input vector to the layer and Nₒ^{F} is the number of neurons (the output vector) in the fully-connected network. The additive term Nₒ^{F} is present due to the bias added to the input to each neuron, and the output size of a fully-connected layer S_{F} is therefore exactly equal to Nₒ^{F}.

Convolutional Neural Networks (CNNs). A two-dimensional convolutional layer works by sliding a kernel of values across a two-dimensional image, performing a multiplication of the kernel and an equally-sized portion of the input image to produce a value for how strongly a feature (represented by the kernel) is present within a given image portion. Since multiple features within an image may be relevant for performing a given task, multiple kernels are learned and multiplied separately across the entire image, producing a set of “feature maps” which represent the strength of each feature across the entire image. For the case where multiple images are fed into a convolutional layer, individual kernels are also initialized and learned separately from each other for each image before the feature map values for each region are then summed together to produce a single value for a given region in the input images, thereby producing a combined feature map which is the result of several different features learned across the different input images. Since only the multiplicative weights within a given kernel must be learned, the total number of learnable parameters within a single two-dimensional convolutional layer may be expressed as:

P^{C}=Nᵢ^{C}kₓk_{y}N_{f}^{C}+N_{f}^{C} (2)

where Nᵢ^{C} is the number of input channels to the layer, kₓ,k_{y} are the x and y dimensions of the kernel, and N_{f}^{C} is the number of output features. For our purposes we can set kₓk_{y}=k², since the original implementation of LatticeNet strictly assumes a square kernel, and the additive term N_{f}^{C} is due to the bias added to each feature map individually. Since the original implementation assumed the input to the layer is zero-padded so that all regions of the input image, including edges, are represented in the resulting feature maps, the total number of “pixels” Sₜₒₜₐₗ^{C} that the convolutional layer will output (assuming a stride of 1) goes as:

Sₜₒₜₐₗ^{C}=N_{f}^{C}A²R² (3)

where A is the number of pins per side for each assembly and R is the number of assemblies in the region. The square term stems from the assumption that the region we are working in is strictly square and that all assemblies have exactly the same dimensions.

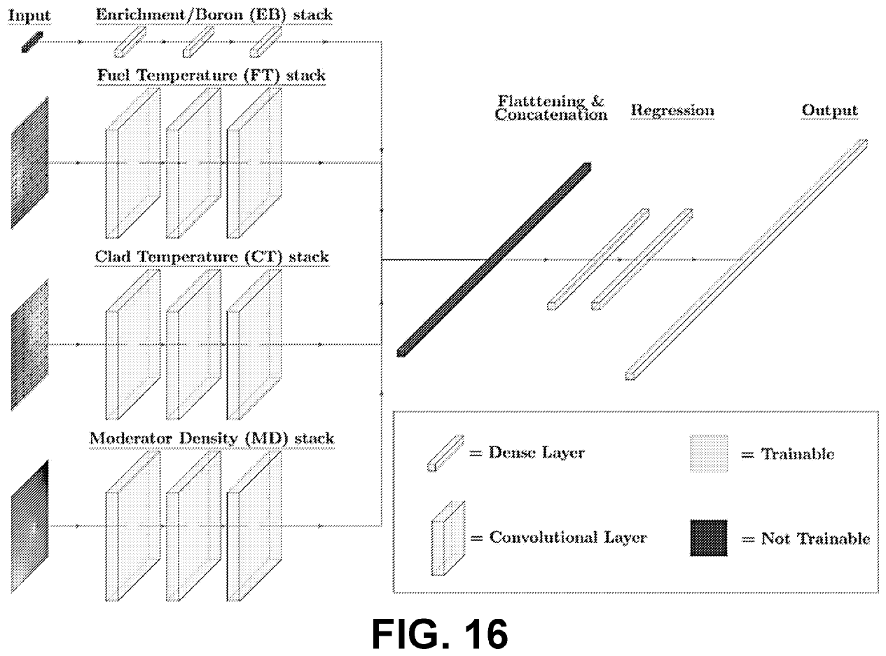

LatticeNet 1.0. The original implementation of LatticeNet (hereafter referred to as “LatticeNet 1.0”) was composed of stacks of multiple sequentially-connected convolutional or fully connected layers, all feeding into a regression stack composed of two fully-connected layers, with a third fully-connected output layer on top of this regression stack. For the convolutional stacks, each layer was allowed to produce between 1 and 25 individual feature maps. The layers of each were then flattened and concatenated into a single vector of values which were fed to the regression stack. The output of the regression stack was then a single vector of values (289 in the reference implementation), corresponding to all pin positions within an assembly. An example diagram of LatticeNet 1.0 is shown in FIG. 16. Performing some initial analysis of the scaling behavior of Equation (2), the terms Nᵢ^{C} and N_{f}^{C} appear to be dominant since they are only able to take on values between 1 and 25. Setting these values to their maximum, and assuming a 4×4 kernel size, the total number of learnable parameters introduced into the network by a single convolutional layer is therefore at most 10,025. Therefore, using three convolutional stacks composed of three convolutional layers each would only introduce 90,225 learnable parameters, well within the capabilities of even CPU-bound network training. These are purely hypothetical upper limits, and the actual number of learnable parameters will be different depending upon choice of hyperparameters, however these numbers give a general indication of how layers/stacks of layers will introduce parameters as their input sizes are changed. The computational issue only becomes apparent when considering the interaction between the convolutional stack(s) and the regression stack.

Performing initial analysis of the scaling behavior of Equation (1), it is not immediately obvious that any terms would be dominant, especially as Nₒ^{F} is limited to at most 2,000 neurons in the regression stack as per the LatticeNet 1.0 configuration. The issue comes when Nₒ^{F} is set to some non-small value, such as 1,000 neurons for example, and Nᵢ^{F} is allowed to grow as large or larger than this value, again set to 1,000 as an example. For such values, the total number of parameters P^{F} introduced by a fully-connected layer may be just a little over one million, but will grow much larger if Nᵢ^{F} is set higher. This is not a concern when discussing the inner layers of the regression stack, as each of these is only allowed to output a vector of size 2,000, meaning the total number of learnable parameters produced by each fully-connected layer may only be, at most, roughly four million. The issue comes in the flattening and concatenation of the output of the convolution stacks and the feeding of this vector as input into the regression stack. The resulting size of the flattened and concatenated convolutional stacks shown in FIG. 16 goes as:

$${S}^{flat} = {\sum }_{j = 1}^{3} {N}_{fj}^{C} {A}^{2} {R}^{2} \qquad ( 4 )$$

where N_{fj}^{C} is the specific number of feature maps at the output of the j-th convolutional stack. It should also be noted here that we have assumed that the number of input image channels to each stack is 1—slightly different equations become relevant when considering a single stack with multiple channels of input images, as described in the LatticeNet 1.2 Section.

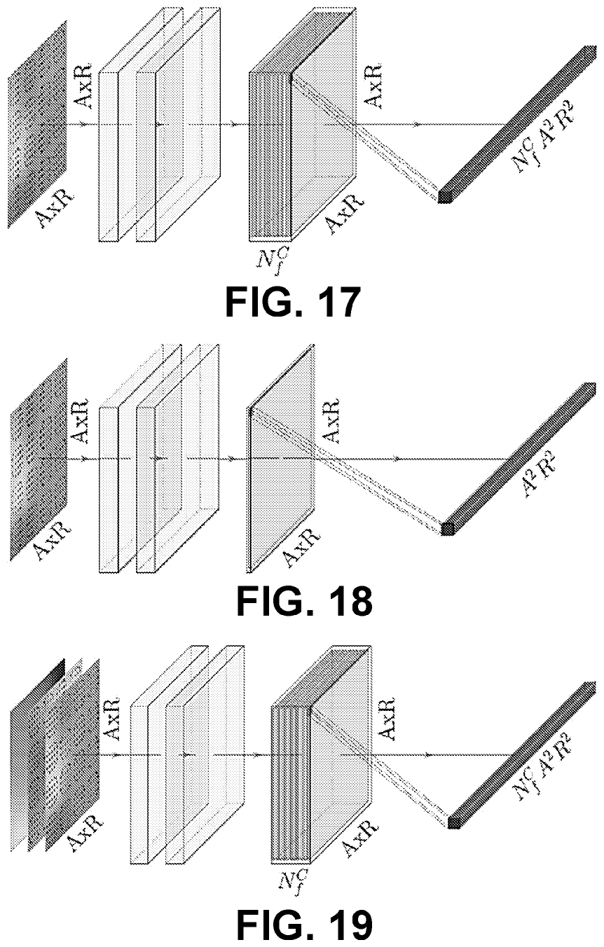

The output of Equation (4) is also the input term of Equation (1). Performing the substitution, we get an expression for the number of learnable parameters within the first layer of the regression stack, P^{F}^{₁}:

$${P}^{{F}_{1}} = {\sum }_{j = 1}^{3} {N}_{fj}^{C} {A}^{2} {R}^{2} {N}_{o}^{F} + {N}_{o}^{F} \qquad ( 5 )$$

where again, N_{fj}^{C} is the number of convolutional filters at the output of the j-th convolutional stack, A is the number of pins per assembly side, R is the number of assemblies in the (assumed square) region and Nₒ^{F} is the number of neurons in the regression layer. It is here we begin to see the issue with with the original LatticeNet architecture configuration. If we assume a region composed of only a single 17×17 assembly, set N_{f1}^{C}, N_{f2}^{C} and N_{f3}^{C} all equal to 10, and set Nₒ^{F} to 1,000, then Equation (5) evaluates to just over 8.5 million parameters. Thus, assuming even an average number of output feature maps produced by each convolution stack, the first layer of the regression stack quickly becomes dominant in terms of the number of learnable parameters introduced, due solely to the size of the images produced by the convolutional stacks. FIG. 17 shows a high-level overview of the mathematical logic occurring for each convolutional stack.

Equation (5) holds for larger regions with multiple assemblies, and evaluating this expression at larger region sizes with hypothetical default values reveals the primary issue with scaling up LatticeNet 1.0. Again assuming (N_{f1}^{C}, N_{f2}^{C}, N_{f3}^{C}, Nₒ^{F})=(10, 10, 10, 1e3), Table VIII gives the estimated number of parameters. As can be seen, for a 2D region roughly the size of a common PWR using quarter-core symmetry (7×7) (ignoring boundary assemblies), the number of parameters approaches half a billion. This is also assuming, of course, that the term in Equation 5 representing the number of neurons in the first layer of the regression stack has an upper limit of 1,000 neurons. In reality, a good value for this hyperparameter when training on large problem sizes might be in the range of several thousands, meaning that the number of parameters could easily crow into the ramie of billions.

TABLE VIII
Number of learnable parameters introduced as
Equation 5 scales to larger region sizes.

| | 1 × 1 | 2 × 2 | 3 × 3 | 4 × 4 | 5 × 5 | 6 × 6 | 7 × 7 |
|---|---|---|---|---|---|---|---|
| # of parameters | 8.671 | 34.681 | 78.031 | 138.721 | 216.751 | 312.121 | 424.831 |
| (millions) | | | | | | | |

While modern at-scale computing capabilities have grown enough that dealing with billions of learnable parameters is no longer an impossible problem, these requirements are still significant enough to place experimentation and usage out of reach for most groups unless the application and problem are carefully planned and constructed. If methods could be devised to reduce the result of Equation (5) then it would be much more feasible to scale up LatticeNet and in turn would make experimentation and application much more worthwhile.

LatticeNet 1.1. One targeted change we can make, to try and preserve the fidelity of the model while reducing computational burden, would be to enforce the requirement that the final layer within each convolutional stack only be allowed to output one feature map. This would force the Σⱼ₌₁³N_{fj}^{C} term in Equation (5) to always evaluate to 3. Even for a 7×7 region of assemblies, the number of parameters required would be roughly 43 million, making training of the model a much more reasonable exercise. FIG. 18 shows a high-level overview of the logic taking place as a result of this change for each convolutional stack. It is worth pointing out that this variant can be thought of as compressing the amount of information in the network, forcing it to express relevant features through a single feature map per TH channel instead of multiple feature maps at the output. Compressing information into a mathematical “latent space” is common in various machine learning approaches, thus it is worthwhile to investigate whether these approaches significantly benefit or degrade performance of the network in terms of error and runtime.

LatticeNet 1.2. Another viable variant of LatticeNet is one where all the input images of reactor data are fed into a single convolutional stack. This sets the upper limit of the term in Equation (5) to be 1 instead of 3; as long as N_{f1}^{C} is kept reasonably low this strategy achieves some computational reduction. One caveat of this change is that the easy separability of the convolutional feature stacks is lost; indeed, this was the original motivation for separating them in LatticeNet 1.0. Another caveat is that this strategy may not actually result in that much “cost savings” if, of course, N_{f1}^{C} is allowed to grow large. FIG. 19 shows a high-level overview of the logic taking place as a result of this change for the convolutional stack. This is again a variant based on effectively compressing the information within the network into a few parameters instead of allowing each stack a large amount of individual feature expression. It should also be noted here that the single convolutional stack with multiple TH inputs shown in FIG. 19 does accurately represent the combination of all convolutional stacks from FIG. 16 into one convolutional stack, as opposed to other diagrams shown in this section where only a single convolutional stack is used as an example.

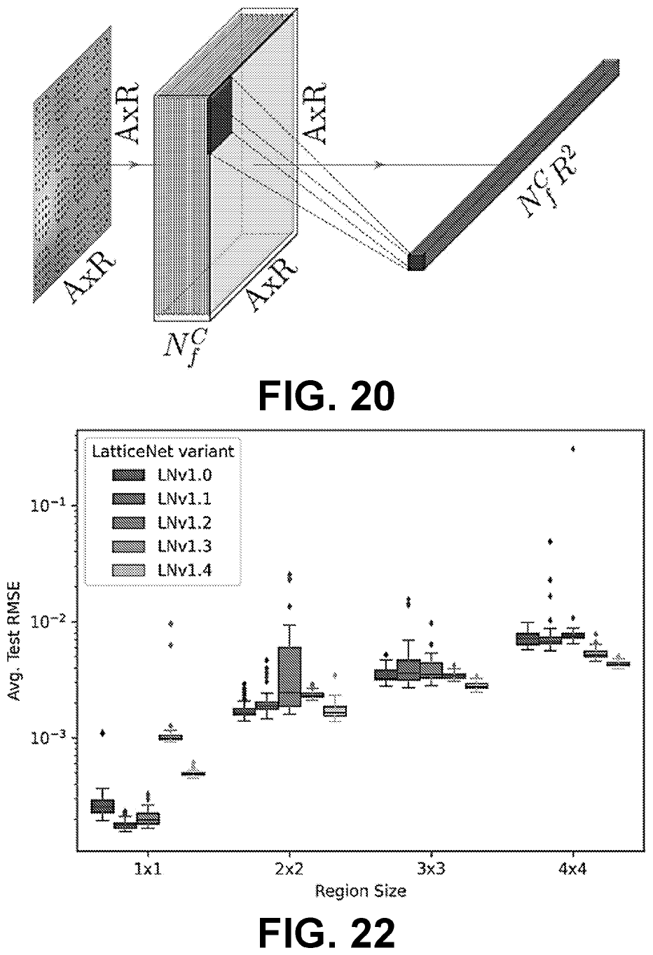

LatticeNet 1.3. One change which can be made, which is more sweeping, would be to restrict the kernel size for all layers in the convolutional stack to be size 17×17, and to enforce a stride (amount by which the kernel displaces in the x- and y-planes after multiplication) of 17. This effectively enforces a user-informed prior on the network, that features which matter should be found and evaluated on a region the same size and shape as an assembly. One benefit of this variant is that it is potentially the most computationally performant variant proposed in this paper, as it removes the squared dependence on the number of pins per assembly side (the A² term) in Equation (5). Even for a 7×7 region the modified Equation (5) would then evaluate to roughly 1.5 million parameters. One drawback of this variant is it carries the potential to miss some fine sub-assembly (pin-level) features. This is because this variant is effectively based on discarding information at a high level, since with a limited number of feature maps and with processing performed on such a large spatial region it is unlikely that a given convolutional stack will be able to effectively learn fine, pin-level variations as well as earlier variants (LatticeNet 1.0-1.2). FIG. 20 shows a high-level overview of the logic taking place as a result of this change for each convolutional stack.

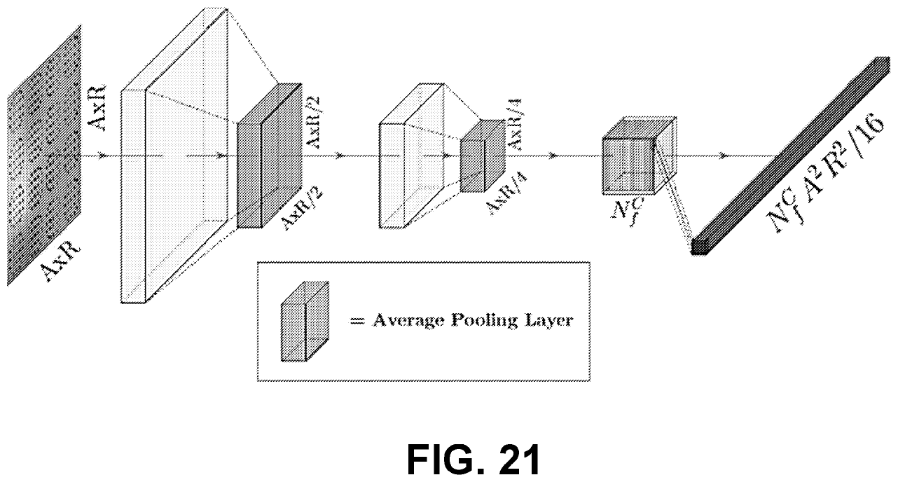

LatticeNet 1.4. The final variant of LatticeNet proposed by this paper uses the downsampling technique known as “Average Pooling” which summarizes the features within a set of images by performing a moving average over a given region of the image. This technique uses a pooling window to significantly reduce the input image(s) in size, resulting in much fewer parameters and a focus on global parameters as network inputs progress through subsequent pooling layers. It is difficult to estimate the exact resulting region size at the end of a stack containing convolutional and pooling layers since the pooling window (which is a hyperparameter) directly affects how much of each image gets sent to the next layers. In general however, a reduction to 25% of original image size is not unreasonable. While pooling can remove a significant amount of spatial information, and indeed this is a property of pooling operations, the potential computational benefits in using pooling are significant enough to warrant investigation. FIG. 21 shows a high-level overview of the logic taking place as a result of this change for each convolutional stack.

Variant Summary. Table IX summarizes the different LatticeNet variants proposed here in terms of the number of parameters estimated by Equation (5) for each variant. The number of output feature maps N_{fj}^{C} at the output of each convolutional stack was set to 10 in all cases, and Nₒ^{F} was set to 1,000, to make these estimations fair. In order to better showcase the potential benefits, the numbers shown are normalized to the number of parameters needed by LatticeNet 1.0. These estimated values remained constant across different region sizes, hence why a dependence on region size is not indicated.

TABLE IX
Estimated number of model parameters in each proposed
variant, normalized to LatticeNet 1.0.

| | LNv1.0 | LNv1.1 | LNv1.2 | LNv1.3 | LNv1.4 |
|---|---|---|---|---|---|
| # of parameters | 100% | 10% | 33% | 0.34% | 25% |

### Results

The results shown here are the product of a two-step process: a hyperparameter optimization step and a subsequent mass training step. In the hyperparameter optimization step, each LatticeNet variant described in Analysis Section has their hyperparameters separately tuned, with 60% of the data (6,000 samples) used as a training set, 20% used as the validation set for evaluating hyperparameter selection, and the remaining 20% used as an independent measure of network performance; the last 20% was never seen by either the neural network optimizer or the hyperparameter optimizer. The hyperparameter optimization methodology used was the exact same methodology developed in previous work by Shriver et al. This methodology combines structured random sampling with a Bayesian hyperparameter selection approach and adaptive trial scheduling/killing to identify optimal sets of hyperparameters. The most-optimal set of hyperparameters for each variant (according to the held-out test data) were then taken and fed to the mass training step, where the dataset is randomly shuffled and where the first 80% of the shuffled dataset is used to train an architecture with the prescribed hyperparameters, with the last 20% always used as a testing set. This process was repeated 50 times for each variant and the seed used to randomly shuffle the data was the attempt number ([0,49]). This strategy is somewhat complicated, however the end effect is that all results shown are the result of training and evaluating the architectures proposed on 50 different train/test splits of the dataset. This two-step process was repeated for all five LatticeNet variants for each dataset corresponding to the four regions under study (1×1, 2×2, 3×3, 4×4).

The neural network architectures were all implemented and trained using TensorFlow 2.0, a robust framework for deep learning research which allows the streamlined development and deployment of neural network architectures on CPUs and GPUs. The distributed training tasks were all implemented using Ray Tune, a work scheduling and hyperparameter training framework which allows the easy deployment of distributed algorithms across multiple nodes and heterogeneous architectures. All training was accomplished using 4 nodes of the Summit high-performance computing system, each of which contains 6 NVIDIA Tesla V100 GPUs and 44 cores (ignoring multithreading). Each model was assigned to train on a single GPU—the number of CPUs assigned to each model was not found to significantly affect the training times for the networks.

When examining the results one should keep in mind that the training process of neural networks is very much a stochastic process as many frameworks (including TensorFlow) take advantage of processes which promote random behavior, including asynchronous memory copies and non-deterministic batch shuffling and random weight initialization schemes which are statistically good for the majority of use cases. Therefore, any trends in behavior gleaned from experiments must be taken in aggregate as an observation based on one or two data samples may simply be due to random chance. It should also be noted that LatticeNet variants 1.0, 1.1 and 1.2 all used gradient clipping, specifically clip normalization with a cutoff of 0.001. This clipping was found to be necessary otherwise models which are based on compressing the information (1.0, 1.1, and 1.2) all suffered significant instability and were prone to have “exploding gradients” otherwise.

Error Comparison. FIG. 22 compares the average RMSE between the predicted and actual normalized pin powers returned by MPACT, evaluated from the test data across all four regions, in order to determine how these networks compare against each other when allowed the maximum amount of data to train. Each individual point either directly drawn or contained in the quartile regions is from computing the RMSE between the answer predicted by the model and the ground truth for each sample separately in the test data, and then taking the average of these values. Table X shows the 25th, 50th and 75th quartiles of the data shown in FIG. 22. Again, it should be stressed that in the comparison shown all variants were trained/evaluated on 50 different train/test splits of the dataset for each region (80%/20%) and that all models were evaluated on identical versions of these 50 splits. k-fold cross validation was not used due to the confounding presence of outliers (discussed further below), thus this large-scale random selection approach was adopted to ensure that we captured average trends and behavior of these models despite these outliers.

TABLE X
25%, 50% and 75% quartile values for the data shown in FIG. 22

| Region | Variant | Q1 | Q2 | Q3 |
|---|---|---|---|---|
| 1 × 1 | 1.0 | 2.274e−04 | 2.571e−04 | 2.906e−04 |
| | 1.1 | 1.665e−04 | 1.770e−04 | 1.847e−04 |
| | 1.2 | 1.818e−04 | 1.977e−04 | 2.235e−04 |
| | 1.3 | 9.732e−04 | 9.952e−04 | 1.048e−03 |
| | 1.4 | 4.770e−04 | 4.900e−04 | 4.994e−04 |
| 2 × 2 | 1.0 | 1.575e−03 | 1.627e−03 | 1.790e−03 |
| | 1.1 | 1.764e−03 | 1.886e−03 | 2.023e−03 |
| | 1.2 | 1.865e−03 | 2.453e−03 | 5.996e−03 |
| | 1.3 | 2.235e−03 | 2.286e−03 | 2.410e−03 |
| | 1.4 | 1.531e−03 | 1.642e−03 | 1.860e−03 |
| 3 × 3 | 1.0 | 3.151e−03 | 3.266e−03 | 3.808e−03 |
| | 1.1 | 3.141e−03 | 3.579e−03 | 4.688e−03 |
| | 1.2 | 3.249e−03 | 3.509e−03 | 4.395e−03 |
| | 1.3 | 3.257e−03 | 3.405e−03 | 3.543e−03 |
| | 1.4 | 2.682e−03 | 2.760e−03 | 2.910e−03 |
| 4 × 4 | 1.0 | 6.289e−03 | 7.166e−03 | 7.905e−03 |
| | 1.1 | 6.393e−03 | 6.775e−03 | 7.341e−03 |
| | 1.2 | 7.212e−03 | 7.514e−03 | 7.904e−03 |
| | 1.3 | 4.955e−03 | 5.169e−03 | 5.558e−03 |
| | 1.4 | 1.177e−03 | 4.276e−03 | 4.453e−03 |

As can be seen, LatticeNet 1.3 and 1.4 perform worse than 1.0, 1.1 and 1.2 for the single-assembly scenario. This is unsurprising, as the 1.1 and 1.2 variants merely force the network to compress its representation of the information while 1.3 and 1.4 actively discard information as the input is propagated through the network. LatticeNet 1.3 in particular appears to do worse by a significant margin, which is also analytically unsurprising since it can (at most) only represent features which can be accurately described at the scale of a whole assembly; fine pin-level features are likely more difficult to generalize at such a large scale. LatticeNet 1.4 at least attempts to preserve a finer amount of information due to the use of Average Pooling, so it does comparatively better. Interestingly, LatticeNet 1.0 also appears to be beaten slightly by both 1.1 and 1.2, which is unexpected considering 1.0 theoretically has the best capability to capture and interpret pinwise variation. It is possible that forcing the compression of information is helpful to the generalization capabilities of the network, a phenomena which has been demonstrated before in deep learning research.

Much more interesting behavior appears when comparing variant error for the 2×2, 3×3 and 4×4 regions. As can be seen, 1.4 appears to be the most performant by a small but noticeable margin for regions which are not 1×1 in size, followed closely by 1.3. LatticeNet 1.0, 1.1 and 1.2, meanwhile, again appear to match closely with each other however appear to suffer increasing error and greater instability in average behavior (more outliers) relative to 1.1 and 1.2 as the region size increases. LatticeNet 1.3 and 1.4, meanwhile, do not appear to suffer any such stability issues beyond the 1×1 region, and indeed appear to be the most performant with respect to increasing region size. This behavior would not necessarily be expected as 1.0 theoretically preserves the same predictive power shown in the 1×1 model with an increased computational cost. One possible explanation for this is that allowing more parameters encourages “memorization” in the network which is avoided by variants which discard information.

The significant jump in error between the single-assembly and all multi-assembly regions is interesting to address, as moving from 2×2 to 3×3 and 3×3 to 4×4 region sizes does not appear to correspond to an equivalent increase in error. This could be explained by the simplified reactor dynamics which take place in a single reflective assembly, where no dynamics between different fuel regions needs to be considered and the only pinwise effect is from changing TH conditions. In contrast, in multi-assembly regions changes to the pin powers come from both the TH conditions locally within an assembly and also from the neutronics effects of neighboring assemblies. Between these two, the cross-sectional changes that come from changing fuel enrichment is doubtless more significant. Based on this assertion and on experimental results, it can be concluded that the problem framing currently used is able to capture the localized dynamics of changing TH conditions relatively well, however it is much more difficult to accurately capture the dynamics of changing fuel regions even for smaller 2×2 regions. This nicely explains the superior performance of LatticeNet 1.0, 1.1 and 1.2 in the 1×1 region, the stark rise in error when moving from single to multi-assembly regions, and the smaller change in relative performance when scaling to larger region sizes.

Concerning the outliers shown in FIG. 22, various experiments not shown here identified a variety of underlying causes for these outliers. One was overfitting, a phenomenon where a machine learning model will begin to “memorize” the training data while losing the ability to generalize to test data. Another was plateauing of the network, where a local optima was found by the network during training which was difficult to escape from. The “exploding gradients” phenomena was also found to affect variants 1.3 and 1.4, although not enough to justify running experiments with gradient clipping as was done for 1.0, 1.1 and 1.2; these three variants were found to be massively unstable without gradient clipping. The exploding gradients issue appears to be similar to the problem noted in the earlier paper introducing LatticeNet, which occasionally saw large increases in the training loss for no discernable reason. While it is possible to determine the source of these instabilities, they were not reliably reproducible, related more to random chance than to specific train/test splits of the data, indicating that all three are tied to the previously-mentioned randomness introduced when training a neural network. Since these instabilities do not have a single central cause and are random, the challenge of solving them is best left as an implementation-specific problem, to be resolved for specific applications. The authors do not feel this significantly undermines the validity of the results shown, as general trends are clear and are the result of a large number of independent runs to ensure statistical validity.

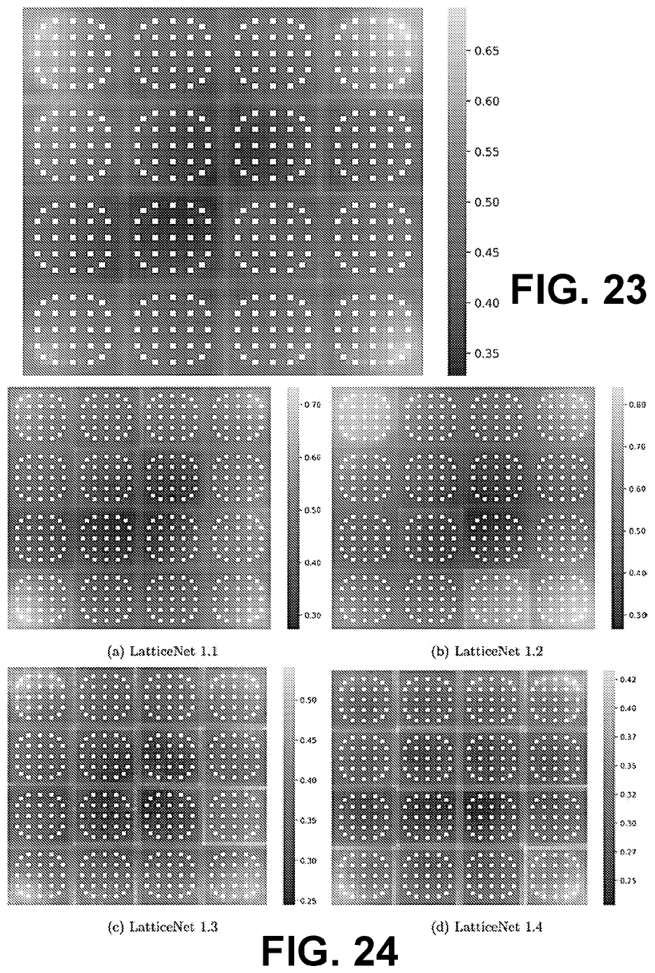

FIG. 23 examines the average pinwise percent error of LatticeNet 1.0 on the 4×4 dataset. The value shown for each pin location represents the average percent error between the model prediction and the actual normalized pin-power values for that pin location. The data shown in FIG. 23 is from using the best-performing LatticeNet 1.0 attempt from FIG. 22 to perform inference on the corresponding test dataset held out during training. From this figure and other results shown below, the network may be managing to learn a lower-order approximation of the underlying physics. There are multiple details within the figure which seem to support this. One is the general observation for the inner assemblies, that the lowest error is at the center of the assembly and the higher tends to be at the boundaries (especially at the corners). Since material changes at boundaries, especially enrichment changes, are some of the most challenging phenomena to accurately model from a neutronics perspective, this behavior aligns with current reactor physics knowledge on the capabilities of lower-order methods. Another observation can be made for those assemblies on the edge of the region, where these corner assemblies have the largest mean error and where a gradient leading from the center to the corner is apparent. Since neural networks perform a high-dimensional fit to the training data, higher relative errors at the corners is exactly what would be expected of such a method when encountering outer limits with a hard discontinuity, such as a corner with two reflectors. It should be strongly stated that the authors do not believe that this behavior is evidence of this or other variants learning to simulate the actual underlying physics. Current deep learning research is unequivocal in the assertion that neural networks are strong pattern and relationship finders, and their generalization capabilities outside of their distribution are often poor. However, for certain high-fidelity features the underlying relationships may be readily reduceable (to first order) to a set of generalized relationships similar to empirically-derived TH equations. Neural networks are essentially a brute-force way to find these relationships, which may partially explain their success in this application thus far.

FIG. 24 examines the pinwise percent error for the proposed of LatticeNet on the 4×4 dataset. Each plot shown is also taken from using the best-performing model for that specific variant from FIG. 22; therefore results shown do not correspond to networks trained on the same train/test split. The minimum and maximum of the average error ranges correspond closely to the behavior seen in FIG. 22 (i.e., variant 1.4 is best). Of particular note is that all variants have the same characteristics as 1.0, where the lowest error is in the center and the highest error is at the corners. LatticeNet 1.1 and 1.2 in particular seem to cleanly reproduce these features, which makes sense as they again focus on compressing instead of discarding information and should preserve local relationships the best relative to 1.0.

An interesting observation can also be made for the LatticeNet 1.3 and 1.4, where the pinwise percent error is noticeably stronger on the all assembly boundaries for both of these variants. This may be attributed to the nature of these variants, where information is actively discarded instead of just compressed. For these variants (particularly 1.3) the forced discarding necessarily removes fine pin-level information which may force the network to rely on learned relationships between the different assembly enrichments instead of more fine-grained TH changes. If this is indeed what is happening, it would explain the overall reduced error for the 1.3 and 1.4 variants compared to 1.0, 1.1 and 1.2 seen in FIG. 22, since at a macroscopic level paying more attention to the fuel enrichment will, to first order, be more correct than paying attention to fine TH features. It would also explain the noticeable error at the assembly boundaries, since these variants may be generally correct in their evaluation however fine-grained TH effects at these boundaries may induce subtle changes which the variants are unable to capture.

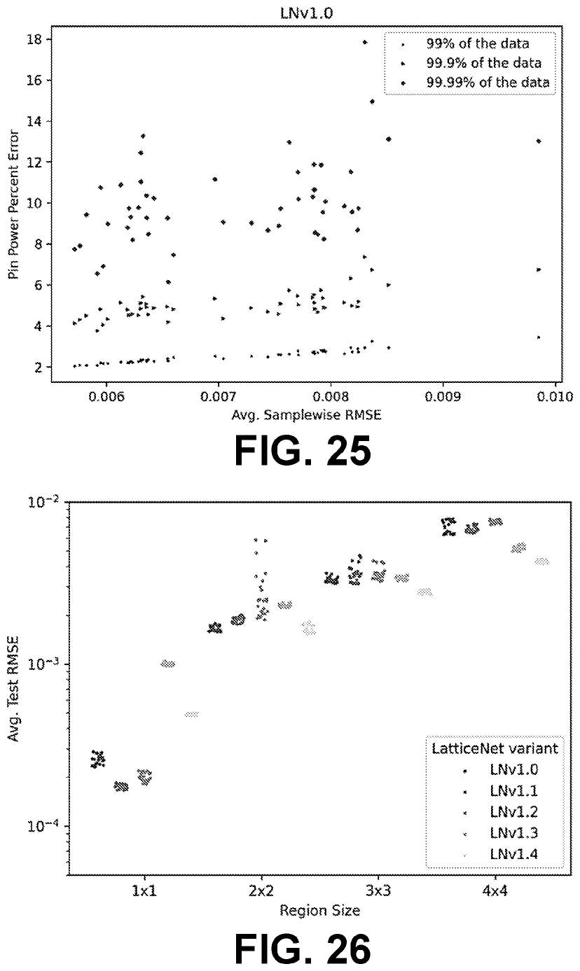

Table XI shows statistics for the best-performing variants across all four regions. The maximum error values for the 1×1 region are in line with the maximum error values reported in previous work of 1.8%. Since we do not consider burnable poisons and thus there is much less network/data complexity, maximum percent errors less than half of what was previously reported are reasonable. For the rest of the regions, it can clearly be seen that the average maximum error tends to increase with region size, becoming largest in the 4×4 region and with even the lowest maximum errors being greater than 8%. In order to examine this trend a little further, FIG. 25 plots the upper limit below which 99%, 99.9% and 99.99% of the pin power percent errors fell under across all 50 LatticeNet 1.0 instances developed in the mass training step, with respect to the corresponding average samplewise RMSE for each. Each point represents the upper limit of pin percent error for a separately trained LatticeNet 1.0 instance. As can be seen, a decrease in the average samplewise RMSE corresponds to a decrease in the bulk error distribution limit, the upper limit below which 99% of the data is located, however this correlation does not hold for determining the upper limit of 99.9% and 99.99% of the data with the trend growing weaker as more of the data is covered. Additional experiments not shown here were not able to discover any relationship between the actual maximum error and the average samplewise RMSE, nor were they able to discover any structure or feature in the training/testing datasets which correlated with the large maximum errors seen in Table XI. Very similar trends were observed for other LatticeNet variants.

TABLE XI
Relevant metrics for the best-performing attempts
across all variants and dataset regions.

| | | | | Max |
|---|---|---|---|---|
| | Vari- | | | Error |
| Region | ant | Avg. Samplewise RMSE | Avg. Pinwise MAE | (%) |
| 1 × 1 | 1.0 | 1.944e−04 ± 6.5e−05 | 1.491e−02 ± 2.9e−03 | 0.79 |
| | 1.1 | 1.558e−04 ± 5.0e−05 | 1.188e−02 ± 2.6e−03 | 0.40 |
| | 1.2 | 1.676e−04 ± 6.5e−05 | 1.295e−02 ± 3.0e−03 | 0.45 |
| | 1.3 | 9.289e−04 ± 3.6e−04 | 6.942e−02 ± 1.7e−02 | 1.69 |
| | 1.4 | 4.515e−04 ± 1.8e−04 | 3.376e−02 ± 6.2e−03 | 1.22 |
| 2 × 2 | 1.0 | 1.395e−03 ± 5.0e−04 | 1.078e−01 ± 2.8e−02 | 2.61 |
| | 1.1 | 1.458e−03 ± 8.0e−04 | 1.164e−01 ± 4.0e−02 | 5.93 |
| | 1.2 | 1.596e−03 ± 6.0e−04 | 1.255e−01 ± 3.9e−02 | 3.11 |
| | 1.3 | 2.103e−03 ± 8.5e−04 | 1.565e−01 ± 3.5e−02 | 5.14 |
| | 1.4 | 1.377e−03 ± 5.8e−04 | 1.020e−01 ± 2.1e−02 | 4.13 |
| 3 × 3 | 1.0 | 2.774e−03 ± 1.0e−03 | 2.168e−01 ± 8.1e−02 | 4.54 |
| | 1.1 | 2.701e−03 ± 1.3e−03 | 2.067e−01 ± 6.7e−02 | 6.30 |
| | 1.2 | 2.803e−03 ± 1.2e−03 | 2.155e−01 ± 7.9e−02 | 10.02 |
| | 1.3 | 3.065e−03 ± 1.1e−03 | 2.289e−01 ± 6.4e−02 | 6.50 |
| | 1.4 | 2.469e−03 ± 1.0e−03 | 1.871e−01 ± 4.1e−02 | 6.56 |
| 4 × 4 | 1.0 | 5.716e−03 ± 2.8e−03 | 4.365e−01 ± 1.4e−01 | 17.05 |
| | 1.1 | 5.605e−03 ± 3.2e−03 | 4.306e−01 ± 1.4e−01 | 37.88 |
| | 1.2 | 6.422e−03 ± 4.3e−03 | 4.919e−01 ± 1.9e−01 | 30.61 |
| | 1.3 | 4.570e−03 ± 2.0e−03 | 3.470e−01 ± 1.0e−01 | 11.39 |
| | 1.4 | 3.944e−03 ± 1.8e−03 | 2.927e−01 ± 8.2e−02 | 8.23 |

With the results shown in Table XI and FIG. 25, one issue with the approach of using neural networks is revealed: there appears to be no way to set or determine the upper bound of a potentially wrong answer. This is in line with existing deep learning research, as neural networks are complex models for which it is hard to analytically prove or derive an upper error bound. The authors do not believe this negates the value of the results shown, as the bulk error distribution (99% of the predicted pin power values) are still reliably within reasonable error ranges for an approximate model. LatticeNet cannot serve as a replacement of high-fidelity physics codes, however as a rough approximation used perhaps in initial design studies it may serve very well.

Computational Comparison. Table XII shows the time it took to train each variant, the inference time for each variant to calculate 10,000 designs of the appropriate region size, and the approximate number of learnable parameters for each variant. The training estimate is the result of 50 separate attempts using a dedicated core and a dedicated GPU from Summit, while the inference estimate is based on 10 repeated inference runs using a single core of similar nodes used to generate the training data. There is little variation in either case since the neural network architectures we used are very simple in terms of computations and do not use iterative solves or other mechanisms which lead to variable runtimes; the primary source of variance is from the hardware itself.

TABLE XII
Training/inference times for all variants. All times are
in seconds, # of parameters is in millions.

| | Model | | | # of |
|---|---|---|---|---|
| Region | version | Training Time | Inference Time | parameters |
| 1 × 1 | 1.0 | 2227 ± 19 | 20.554 ± 0.101 | ~23.3 |
| | 1.1 | 1841 ± 42 | 8.282 ± 0.111 | ~5.15 |
| | 1.2 | 1299 ± 31 | 5.717 ± 0.083 | ~9.29 |
| | 1.3 | 909 ± 32 | 0.769 ± 0.0247 | ~1.17 |
| | 1.4 | 1416 ± 37 | 6.058 ± 0.064 | ~4.41 |
| 2 × 2 | 1.0 | 4008 ± 43 | 52.544 ± 0.270 | ~35.01 |
| | 1.1 | 2557 ± 66 | 25.226 ± 0.088 | ~7.28 |
| | 1.2 | 1976 ± 52 | 13.512 ± 0.122 | ~16.74 |
| | 1.3 | 1523 ± 51 | 1.331 ± 0.030 | ~2.37 |
| | 1.4 | 2146 ± 82 | 16.250 ± 0.165 | ~3.96 |
| 3 × 3 | 1.0 | 10322 ± 69 | 144.885 ± 0.312 | ~175.39 |
| | 1.1 | 4101 ± 80 | 38.312 ± 0.210 | ~8.17 |
| | 1.2 | 3788 ± 62 | 39.902 ± 0.101 | ~24.34 |
| | 1.3 | 2202 ± 94 | 1.397 ± 0.045 | ~1.02 |
| | 1.4 | 2882 ± 117 | 18.019 ± 0.102 | ~6.817 |
| 4 × 4 | 1.0 | 13129 ± 126 | 204.655 ± 0.506 | ~165.73 |
| | 1.1 | 6578 ± 120 | 102.279 ± 0.237 | ~31.13 |
| | 1.2 | 4637 ± 140 | 41.0619 ± 0.166 | ~31.77 |
| | 1.3 | 3041 ± 154 | 2.65 ± 0.032 | ~3.92 |
| | 1.4 | 4004 ± 163 | 33.620 ± 0.185 | ~3.59 |

As can be seen, the computational benefits of the proposed variants are significant. For the 1×1 region, the training time of 1.1 and 1.2 is already significantly less, with the inference time less than half of what the 1.0 variant requires. The gap between 1.0 and all other variants in terms of training and inference time only grows as the region size grows, where for the 4×4 region all proposed variants require at most half the training time of 1.0. Most interesting for this region is the inference time results, where 1.0 is 5× more expensive than all other variants, a difference even more stark than that seen in the training times. We believe this is due primarily to the batching scheme used in network training, where memory transfer times between the CPU and the GPU may be a dominant expense relative to the compute required for models with a small number of parameters. If this is the case, the training times seen in Table XII may be subject to substantial improvement with larger batch sizes, although such improvement is again an implementation detail best done by the user themselves as error statistics may change with batch size. Regardless, the benefits of enforcing particular architectural choices with the goal of decreasing the training/inference time are obvious for the regions under study. The baseline version of LatticeNet clearly scales unreasonably to larger region sizes, to the point where scaling the network to a full quarter-core would be expensive at best and unrealistic at worst. The variants proposed allow for vastly improved training and inference times which makes future exploration and extension to full-core prediction much more viable. While LatticeNet requires a significant up-front investment in terms of compute and training data (the 1×1, 2×2, 3×3 and 4×4 datasets required 34, 211, 290 and 246 node-hours to generate in total using a 32-core node) the computational benefits are apparent for applications which require brute-force, high-speed evaluation of many configurations. It is worth restating that the inference time shown was the time taken by the model to make a prediction on all 10,000 data samples, not each sample individually. Therefore, it can be estimated that LatticeNet 1.3, for example, would take approximately 0.3 milliseconds to compute the fine pinwise distribution of a 4×4 region using a single core. This is worth restating as attempting to optimize this architecture for inference, which is widely done but is not attempted here, could produce even lower runtimes than shown in Table XII, which may greatly benefit applications which need high throughput above other concerns.

Speaking towards the number of parameters indicated in Table XII, it is interesting to note that there appears to be a general trend upwards in the number of learnable parameters, however this trend is not absolute, with some variants having less parameters than their predecessors in previous regions. This is not wholly unexpected, as we performed hyperparameter optimization for each region and variant combination independently. Therefore, the number of learnable parameters shown is a result of a network being created and specifically trained for the dataset corresponding to a given region. Over the course of the optimization process it may be that, for the specific trends present in the dataset, one configuration of hyperparameters is more optimal versus another which would be more optimal in a larger region. Therefore, when examining these variants it is far more useful to compare the actual performance statistics as opposed to the number of parameters in order to gauge how effective a model will be and how efficient it is to train said model. The number of parameters shown here is just for completeness and to show that our estimation in Table IX of the reduction in number of learnable parameters by each of these variants is not unrealistic compared to the empirical reductions we see in Table XII.

Impact of Region Size on Accuracy. To examine the question of how well the proposed variants scale to larger problem sizes of interest, FIG. 26 plots the individual points in FIG. 22. In order to avoid examining outliers, for this figure only the data points in the 50% of the data centered around the median (first and third quartiles from Table X) were used. Based on the results shown and the trends seen in FIG. 25, LatticeNet 1.4 is expected to maintain its superior performance, with 1.3 expected to follow closely behind. Given that a region of size 7×7 (corresponding to a full quarter core) is desired, we might expect the average RMSE for the 1.3 and 1.4 variants to be less than or equal to 0.01 for such a problem size, with a correspondingly lower bulk error distribution limit (relative to their peers). Meanwhile, LatticeNet 1.0, 1.1 and 1.2 are expected to achieve an average RMSE greater than 0.01 and might be expected to achieve a much higher bulk error distribution limit. These trends, while not perfect, provide a clear impetus to favor the LatticeNet 1.3 and 1.4 architectures in future research.

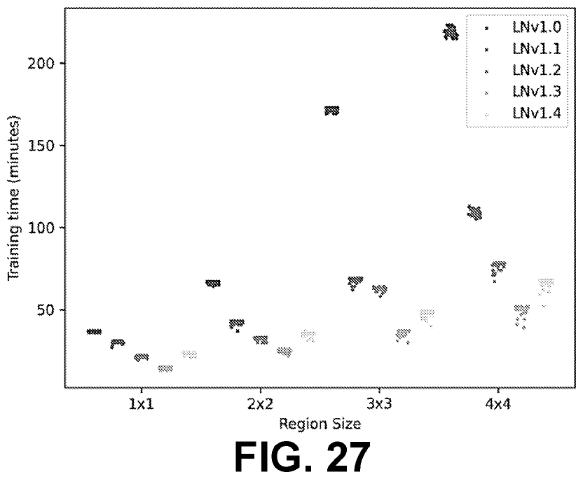

FIG. 27 shows individual points of the data from Table XII. From the trends shown it is clear that the training time for LatticeNet 1.0 might be expected to grow unreasonably for a 7×7 region, with 1.1 following behind. By comparison, 1.2, 1.3 and 1.4 seem to have a much lower increase in training time with respect to region size, with LatticeNet 1.3 continuing to be the least expensive to train. Extrapolating these results out, even for a full quarter-core the training time could reasonably be expected to be less than two hours for 1.3 and 1.4, again indicating that future research should favor these two architectures over 1.0, 1.1 or 1.2.

In this study we have analytically shown that the estimated number of trainable parameters required by the original LatticeNet architecture for reactor parameter predictions grows unreasonably large when taking on problem sizes larger than a single assembly. We identify the root cause of this explosion in the number of parameters, and suggest four variants of LatticeNet focused on reducing this computational load. We generated four datasets of successively larger region sizes composed of multiple assemblies with varying enrichments and TH distributions. We performed hyperparameter optimization for all variants on all of these datasets independently, and then trained 50 versions of each architecture using these best hyperparameters with different training/testing splits in order to determine the average statistical behavior. The results show that for regions greater in size than a single assembly, those variants which focus on discarding information (1.3 and 1.4) consistently perform better than both the baseline LatticeNet (1.0) as well as variants which are focused on compressing information (1.1 and 1.2). We also show that the maximum error of a given model appears to be random, although reducing the average statistical error corresponds to a decrease in the bulk error distribution limit which 99% of the data resides under. The ceiling of this error seems to be tied to the variant under consideration, with LatticeNet 1.3 and 1.4 having the lowest ceilings out of all variants. The training/inference time for both of these is less than the 1.1 and 1.2 variants and much less than the time required by LatticeNet 1.0.

For problems concerning only a single assembly we can make the recommendation to stick with the original proposed LatticeNet architecture or one of the compression-based variants (1.1 and 1.2). These variants appear to most readily preserve fine pin-level features, and for the case of an assembly with uniform enrichment and varying pinwise TH conditions, all three appear to be satisfactory. LatticeNet 1.1 and 1.2 appear to do better than 1.0, however it is not clear how well these architectural features might translate to physical scenarios which include burnable poisons; more research is needed to make an accurate determination.

For problems composed of more than one assembly we can easily make the recommendation to use the either LatticeNet 1.3 or 1.4, depending on preference and on application. LatticeNet 1.4 is the clear winner in terms of error statistics, and on average is only approximately 33% slower to train than LatticeNet 1.3. Thus, LatticeNet 1.4 is the clear solution if one desires a model that is as accurate as possible while still staying computationally performant. If training and inference speed is more important than any other factor, we can instead recommend using LatticeNet 1.3, which is expected to provide almost the same error as LatticeNet 1.4 with the fastest training time and with an inference time at least 15× less than any other architecture. It should also be mentioned that investigating the scaling of these models now is very worthwhile, since this work is concerned only with larger two-dimensional problems. Attempting to apply three-dimensional convolutional networks on fully 3D assemblies or even full cores might cause these hypothetical numbers to grow much larger.

The models developed in this work have been shown to be very performant computationally speaking. In particular, on a single core even the largest model took approximately 0.02 seconds to compute a high-fidelity pin power distribution corresponding to a square region of 16 assemblies. The smallest model, even conservatively estimating runtime, took approximately 0.3 milliseconds to accomplish the same task. Given that neural networks are readily scalable depending on application and use case, the potential speedups afforded by using neural network-based models is apparent. Significant improvement to reduce both training and inference time is possible, meaning that these results should be seen only as preliminary estimates of the potential computational savings of using these models.

The methodology that was originally used to generate LatticeNet's training data was based on placing two or more random points, or vertices, on a 2D grid corresponding to the size of the problem under consideration, e.g. a 17×17 grid in the case of a single 2D reflective PWR assembly. Each of these vertices is then assigned a random value in the range between which the thermal hydraulics curve will vary, e.g. a moderator density curve might vary between 0.66 and 0.743 g/cc and thus a limited number of moderator density vertices would be allowed to take on random values in this range. For points on the grid which are not vertices, the point value is calculated by taking a weighted average of the distance between a given point and all vertices, where the weight is a modified form of the inverse euclidean distance. Thus, multiple random curves can be generated which “look” real, in that points which are close to vertices take on values close to the vertex value and these points follow a gradient from vertex to vertex. LatticeNet's original training data varied multiple TH parameters simultaneously according to this methodology, namely fuel temperature, clad temperature and moderator density.

Next, we develop multiple “physically adversarial” TH datasets specifically intended to provide a challenge to previously produced variants of LatticeNet. The term “physical” comes from the fact that we are not generating these datasets using known adversarial methods relying on mathematical noise distributions or intimate understanding and influence of the model/training data. Instead, we develop novel input/output features which are, statistically speaking, highly unlikely or impossible to have been in LatticeNet's training data but which we would expect a full lattice code such as MPACT to correctly compute. We then evaluate these physically adversarial TH examples using the previously produced LatticeNet variants, and examine trends which can be seen in the model error for these examples. In this way, we can begin to determine areas where LatticeNet might be weak, and can develop methods which counteract or resolve these weaknesses.

Methods to generate new, unique and out-of-distribution physically adversarial test samples for LatticeNet are identified, and new test datasets generated using these methods described. The performance of the different LatticeNet variants on the datasets examined, some of the more interesting trends seen therein discussed, and some technical analysis to resolve discrepancies is provided. An overview of the results gleaned from the disclosure and the earlier analysis is provided.

### Datasets

In order to focus our efforts and avoid considering the effects of multiple different TH distributions in combination, we apply our physically adversarial dataset generation methodologies to each class of input TH distribution separately. For each adversarial distribution, the other assembly design parameters (assembly enrichment, boron concentration) and those TH distributions not under study were held constant. All adversarial TH datasets described were generated within a single reflective assembly with the assembly enrichment uniform across the assembly and with this enrichment value held constant for all data points. This was to avoid capturing the neutronics effects of multiple assemblies with varying fuel enrichments or (potentially) interface effects between assemblies. Table XIII gives a summary of the allowed ranges of values for the physically adversarial TH problems.

TABLE XIII
Allowed parameter ranges for physically adversarial TH examples

| Target TH Parameter | Parameter | Value Range | |
|---|---|---|---|
| Moderator Density | Moderator Density | 0.66-0.743* | g/cc |
| | Fuel Temperature | 626° | C. |
| | Clad Temperature | 290° | C. |
| | Fuel Enrichment | 1.8% | |
| | Boron | 700 | ppm |
| Fuel Temperature | Moderator Density | 0.7 | g/cc |
| | Fuel Temperature | 286-1326*° | C. |
| | Clad Temperature | 290° | C. |
| | Fuel Enrichment | 1.8% | |
| | Boron | 700 | ppm |
| Clad Temperature | Moderator Density | 0.7 | g/cc |
| | Fuel Temperature | 626° | C. |
| | Clad Temperature | 286-356*° | C. |

| | |
|---|---|
| Fuel Enrichment | 1.8% |
| Boron | 700 |

*Except for the “Four Corners” dataset; see Table XIV

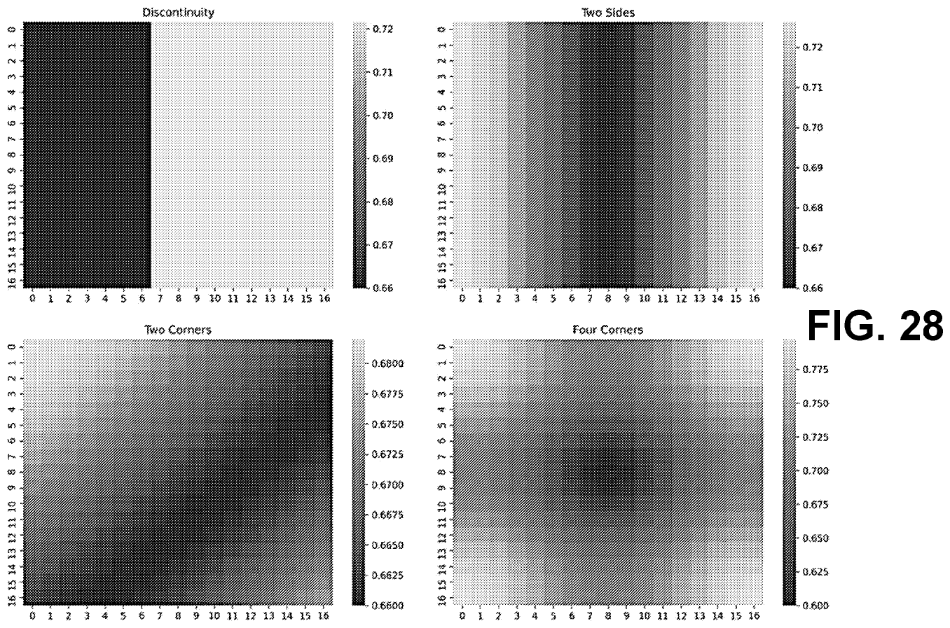

Since we know exactly the methodology used to generate the TH curves, it's straightforward to generate new and unique distributions which are statistically unlikely to be in the training data. Any methodology which uses a different source structure, instead of random point selection and interpolation as previously described, is likely to generate new distributions not seen in data generated via the original methodology. We describe below four different structured data generation methodologies distinctly different from the original. Since our goal is to robustly evaluate the generalization capabilities of LatticeNet for all TH inputs separately, we apply these methodologies to the moderator temperature, fuel temperature and clad temperature distributions separately, using each to produce 100 different adversarial examples. We therefore produced 1200 single-assembly calculations with adversarial TH distributions, 400 for moderator density, 400 for fuel temperature and 400 for clad temperature. Example plots of each of these methodologies being applied to generate adversarial moderator density inputs can be seen in FIG. 28.

Discontinuity. This dataset is focused on determining whether LatticeNet is able to effectively capture the neutronics effects from a discontinuous jump in the TH input. This discontinuity is randomly placed on the x-axis of the assembly and spans the entire y-axis, producing a discontinuous “wall” roughly in the middle of the TH input. On either side of this discontinuity, TH values were kept uniform to whichever value their side of the discontinuity was set at. Since LatticeNet's training data generation was based on placing multiple points randomly on a grid and assigning random values, it is impossible for any distribution seen in the training data to match these randomly generated discontinuities. While a discontinuous TH condition is highly artificial and would not at all be expected in “real” simulations, it is worthwhile to check and see if LatticeNet is able to predict the same distribution of pin powers as computed by MPACT when exposed to TH data that is significantly unique and different from the training data—and which could feasibly be input by a user. The algorithm used to generate this discontinuity is shown in Algorithm 1.

Algorithm 1 Generate discontinuous TH curve

| | |
|---|---|
| Require: lower | {floor of discontinuity} |
| Require: upper | {maximum allowed value of other side of discontinuity} |
| Require: A := 0.0 | {A is an array of dimension 17x17} |
| d := lower + urand(0, upper) | {urand(a, b) generates random float in [a, b]} |
| x_{d} := irand(2, 14) | {irand(a,b) generates random integer in [a, b]} |

```
  for x in range(17) do
    for y in range(17) do
      if x < x_{d} then
        A[x][y] = lower
      else
        A[x][y] = d
      end if
    end for
  end for
  return A
```

Two Sides. This dataset is focused on determining whether LatticeNet is able to effectively capture the neutronics effects from a sinusoidal TH curve, with the curve having a guaranteed maxima at y=0 and a varying period length either shorter or longer than the length of the assembly. The maxima and minima of this function are a random value in the allowed ranges shown in Table XIII, and the lowest value from Table XIII, respectively. All x values for a given y are set exactly the same. In this way, we sought to determine whether smooth variation of the moderator density, with peaking take the form of a wave instead of being focused in one or more vertices, would still be accurately captured and predicted on by LatticeNet. The procedure for generating this random curve is shown in Algorithm 2.

Algorithm 2 Generate sinusoidal TH curve between y = 0 and y = 17

| | |
|---|---|
| Require: lower | {floor of sinusoid} |
| Require: upper | {maximum allowed upper value of simsoid} |
| Require: A := 0.0 | {A is an array of dimension 17x17} |
| s := irand(7, 13) | {irand(a, b) generates random integer in [a, b]} |
| d := urand(0, upper - | {urand(a, b) generates random float in [a, b]} |
| lower) | |
| for x in range(17) do | |
| for y in tange(17) do | |

$A [ x ] [ y ] = lower + 0.5 ( cos ( \frac{y π}{s} ) + 1 ) d$

end for
end for
return A

Two Corners. This dataset introduces a sinusoidal curve varying along the diagonal of the assembly, similar to that seen in the previous dataset. The maxima and minima of this curve are a random value in the allowed ranges shown in Table XIII, and the lowest value from Table XIII, respectively. The purpose of this dataset was again to study the effect sinusoidal variation, however varying in a uniform way between two corners instead of following an increasing/decreasing trend along a given axis. The procedure for generating this random curve is shown in Algorithm 3.

Algorithm 3 Generate sinusoidal TH curve between (x, y) = (0, 0) and
(x, y) = (17, 17)

| | |
|---|---|
| Require: lower | {floor of sinusoid} |
| Require: upper | {maximum allowed upper value of sinusoid} |
| Require: A := 0.0 | {A is an array of dimension 17x17} |
| s := irand(7, 13) | {frand(a, b) generates random integer in [a, b]} |
| d := urand(0, upper - | {urand(a,b) generates random float in (a, b]} |
| lower) | |
| for x in range(17) do | |
| for y in range(17) do | |

$A [ x ] [ y ] = lower + 0.5 ( cos ( \frac{( x + y ) 0.5 π}{s} ) + 1 ) d$

end for
end for
return A

Four Corners. This fourth and final adversarial TH dataset is focused on providing a shape where the minima is in the center of the assembly and a gradient is followed to the corners which have the maximum value of moderator density. In this case, there is no random variation of the location of the minima (it is always in the center of the assembly) and there is no variation of the actual function shape. The only source of variation is the value of the function at the four corners of the assembly. The floor of the function is set below what was allowed in the original training data, and the maximum allowed value for the corners is set above the limits of the original training data. Therefore, this adversarial methodology evaluates the ability of LatticeNet to make a correct prediction given a TH input with a strong gradient across the assembly and with inputs that are outside the limits of the original training data. The upper and lower limits allowed for the different classes of TH inputs are shown in Table XIV The procedure for generating this random curve is shown in Algorithm 4.

TABLE XIV
Out-of-distribution parameter ranges for
the “Four Corners” datasets.

| Parameter | Value Range | |
|---|---|---|
| Moderator Density | 0.6-0.8 | g/cc |
| Fuel Temperature | 226-1400° | C. |
| Clad Temperature | 226-400° | C. |

Algorithm 4 Generate sinusoidal TH curve with a peak at all four
corners and a trough in the assembly center

| | |
|---|---|
| Require: lower | {floor of function} |
| Require: upper | {maximum allowed corner values} |
| Require: A := 0.0 | {A is an array of dimension 17x17} |
| d := brand(0.0, upper - | {urand(a, b) generates random float |
| lower) | in [a, b]} |
| for x in range(17) do | |
| for y in range(17) do | |

```
    ${x}_{c} = 0.25 ( cos ( \frac{x π}{s} ) + 1 ) d$
    ${y}_{c} = 0.25 ( cos ( \frac{y π}{s} ) + 1 ) d$
```

```
    A[x][y] = lower + x_{c} + y_{c}
  end for
end for
return A
```

### Results

All results shown use variants of LatticeNet which have already been developed/trained in previous work, namely the single-assembly variants. We follow the exact same naming scheme given therein, where all variants are denoted “LatticeNet 1.x”, where x denotes a specific architectural decision/change which specifically separates the variant from others. Here we take these existing variants and use them to perform inference on the datasets described in Datasets Section, and do not, at any point, re-train these variants to account for the new training data. For all intents and purposes, this work can be considered a follow-on paper discussing the TH generalization aspects of the variants developed, where these aspects were out of the scope of the reference paper.

We briefly describe the different LatticeNet variants used. LatticeNet 1.0 is the baseline version of LatticeNet, and is the most computationally expensive variant as it separates all TH parameters into separate processing stacks before combining this data and regressing against the target output parameters. LatticeNet 1.1 compresses the output of these TH stacks to a single whole-assembly representation, compressing the amount of information the network is actually allowed to propagate forward. LatticeNet 1.2 uses a well-known property of neural networks where all inputs are concatenated into a single input image with multiple “channels” of information, analogous to red-green-blue channels of information in modern imaging data. LatticeNet 1.3 and 1.4 from the reference paper focus on discarding fine pinwise information in favor of more global features, and thus were found to perform much worse on single-assembly calculations. Therefore, we do not consider LatticeNet 1.3 or 1.4 in this work.

Since it is difficult to accurately summarize error for pin power distributions across multiple such distributions, we have elected here to show the full distribution of errors as well as the maximum pinwise errors across for all LatticeNet variants given a particular adversarial dataset. This is in the interest of being as forthright as possible about how the error is distributed and where the majority of the error is concentrated, as population-based error statistics may be deceptive when applied across many similar distributions.

Moderator Density. Here we examine the performance of all three LatticeNet variants for the physically adversarial moderator density datasets specifically. It's worth noting that these examples are expected to be most difficult for the neural network to get right, as changing the moderator density has a direct and significant effect on neutron moderation.

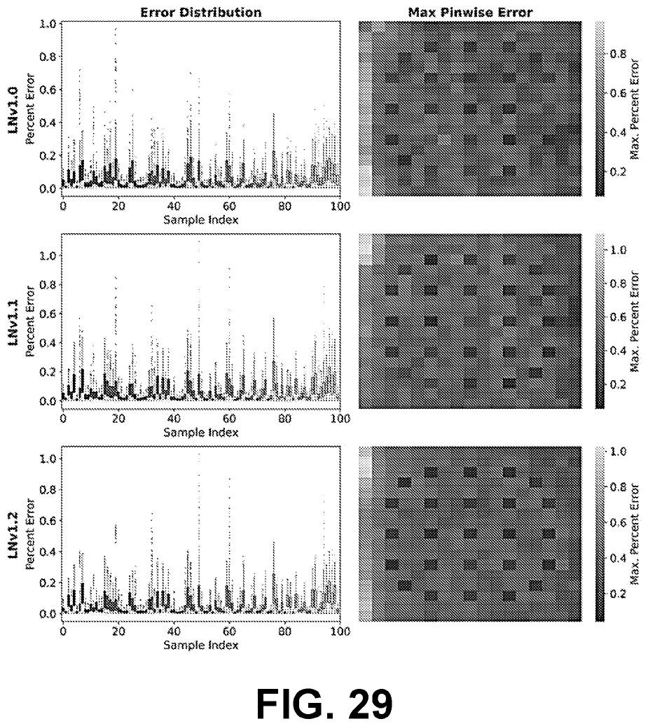

The left-hand side of FIG. 29 shows the percent error distributions across all variants for the Discontinuity dataset. As can be seen, while some of the predictions for the Discontinuity dataset approach or exceed 1% error, the bulk distribution of error in all cases is concentrated below 0.5%. Interestingly, the sample with the highest error is not consistent between variants, with LatticeNet 1.1 and 1.2 having greater than 1% maximum error for samples which LatticeNet 1.0 achieves less than 0.8% maximum error on. The authors do not believe that this is conclusive evidence that LatticeNet 1.0 is superior to the 1.1 or 1.2 variants, since the differences are small enough to feasibly be within the realm of statistical noise. These differences might just as well be explained by the neural network training process forcing the different variants to settle into different local optima which randomly favor one set of examples over another. Nevertheless, these results are encouraging, as they show that in aggregate the majority of the error remains below manageable levels even when physical discontinuities which have little grounding in reality—and no presence in the training data—are allowed.

The right-hand side of FIG. 29 shows the pinwise maximum percent error across all 100 examples in the Discontinuity dataset. Immediately obvious is that the maximum error consistently appears at the left boundary, and this trend continues upwards across the entire line at x=0 for all variants. We might expect, knowing that the discontinuities appear between x=2 and x=14, that the errors would be concentrated randomly between or around the center of the assembly. The bias towards the left-most boundary may indicate that the network has little issue with the discontinuity itself, and that instead there are edge effects at play which are confusing the network in all three cases. Since convolutional neural networks move multiplicative filters across the input image and LatticeNet specifically uses zero-padding of the image edges to capture edge effects, it's not impossible that the relationships learned by the network are dependent on capturing certain edge effects which may be getting thrown off by the presence of a flat distribution at the edge. We leave further analysis of why the variants all had consistently higher error to future work, as analyzing the high-dimensional internals of the network to understand specific features exactly is outside the scope of this research.

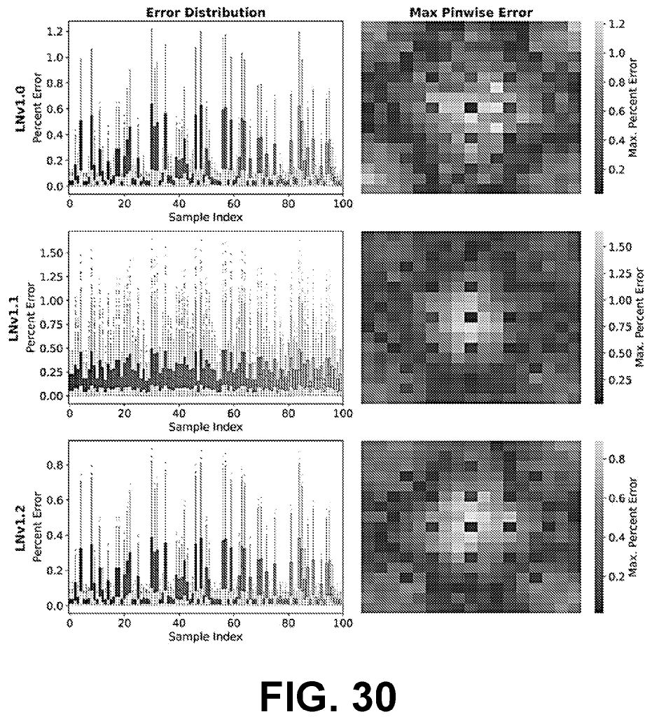

The left-hand side of FIG. 30 shows the distribution of error for the “Four Corners” dataset. As a reminder, the function used to generate this dataset, Algorithm 4, consistently produced a lower bound at 0.6 g/cc and was allowed to randomly select a maximum value up to 0.8 g/cc. Thus, all examples in the Four Corners dataset had at least one, and sometimes five, regions in the moderator density curve which were outside of the range of values the network was originally trained on. Knowing this, the results shown for all three variants are interesting, as all samples have the bulk of their error distributions below 0.8% even with worst-case outliers (LatticeNet 1.1). It's interesting to note however that LatticeNet 1.1 produces error distributions with large numbers of outliers for nearly all samples, and that many of these outliers are quite clearly above 1% error. This indicates that generally the error distributions produced by this variant for extreme out-of-training examples may be roughly correct but subject to significant and perhaps unpredictable error relative to the distributions produced by other variants.

The right-hand side of FIG. 30 shows maximum pinwise errors in the “Four Corners” dataset. As can be seen in all three plots there is consistently higher error at the corners of the assembly, followed by a “valley” of lower error moving towards the center followed by a higher concentration of error in the center itself. One interesting component of these plots is that there appears to be a visible gradient in this error progression, which might not initially be expected as neural networks are pointwise learners with no way to communicate gradient information between inputs, at least in LatticeNet. This perhaps tells us that the relationships being learned consistently may not be strictly pointwise in nature, and may be (roughly) continuous. Another interesting feature of these plots is that they demonstrate that all three variants are able to provide answers with an error not incredibly far from the ground truth even for examples significantly outside of the training distribution, indicating that these learned relationships may be generally exploitable beyond the data regions in which they were learned.

The bulk of the error distributions for all variants is low, below 0.2% for the Two Sides dataset and below 0.1% for the Two Corners dataset. Since both of these datasets are composed of sinusoidal functions with random period and amplitude, which likely looks much closer to the pseudo-random TH curves the variants were trained on, this behavior is unsurprising considering the levels of error seen from the Discontinuity and Four Corners datasets. The major insights we can glean from these results are mostly in support of earlier observations, where qualitative statements on expected error and behavior with respect to the training data are the only factual statements that can be made at this time.

Fuel Temperature. We now consider the same types of randomly generated datasets as described in the Datasets Section, however this time applied to fuel temperature instead of moderator density. These examples are not expected to be as difficult for the network to predict, as changing the fuel temperature primarily drives the Doppler effect in changing the microscopic cross section of the fuel which is small compared to other effects for non-transient scenarios.

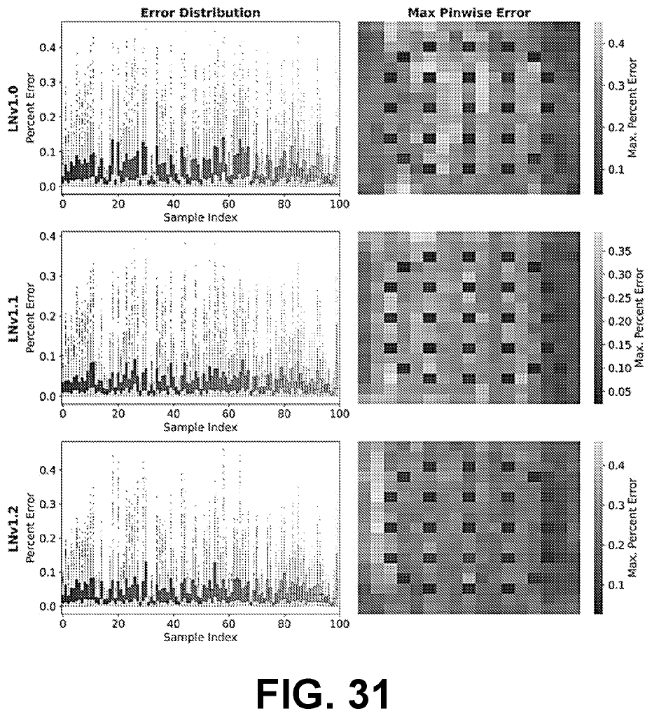

FIG. 31 shows the error distribution and maximum pinwise error for datasets with a physical discontinuity. Similar to earlier results, the large majority of the errors have the bulk of their error distributed at or below 0.1% although there are some single distributions with noticeably higher bulk error which don't appear consistently across all three variants. Also similar to the phenomena seen in FIG. 29, we see a large number of outliers indicated for nearly all examples across every variant, which may indicate that while the general error is low and rather predictable the maximum errors for each variant may be random and relatively unpredictable.

One interesting feature of the plots shown in FIG. 31 is that all three variants appear to be a partial inversion of the trends we see in FIG. 29. The error now appears to be higher in the left and middle regions of the assembly up to a rightmost boundary which is consistent with the upper limit of where the discontinuity was allowed to be placed (x=14). Based on this behavior we can again hypothesize that the network may not have an issue with the discontinuity itself, but with being asked to predict at the lower limit of its training regime. Nonetheless, these results confirm that the developed LatticeNet variants appear to stay robust even under physical discontinuities in the fuel temperature input.

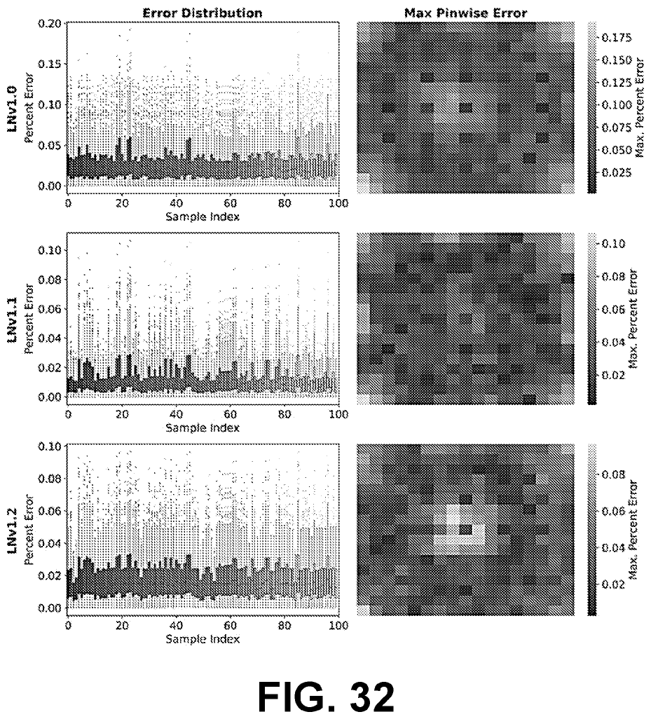

FIG. 32 shows the corresponding error distributions and max pinwise error for the Four Corners dataset. In the plots on the left-hand side we see phenomena similar to that seen in FIG. 31, where nearly all test samples have at least a few significant outliers relative to the bulk distribution of error. Of course, it's also immediately obvious that LatticeNet 1.0 has a maximum error roughly double that of the other variants under study. This does not appear to be caused by a single outlier, as it can be seen that many (almost all) of the samples in the LatticeNet 1.0 distribution plot have outliers greater than 0.1%. As the test samples are exactly the same between all variants, it's not clear why the error was generally higher for LatticeNet 1.0 since the average level which the bulk of the error is at or below seems to be close to the same for all three variants. The authors are hesitant to take this as evidence that one variant is superior or inferior relative to another, since neural networks are statistical machines and these particular variants may just be exhibiting specific, non-consistent biases as a result of their training data or the training process. What is clear from these results, however, is that even worst-case performance for out-of-distribution inference examples could reasonably be expected to produce a pinwise percent error around 0.3% or less based on the current test data.

The maximum pinwise errors shown on the right-hand side of FIG. 5 show once again a gradient where the highest error tends to be at the corners and center of the assembly, with a gradient of lower error moving from the corners to the center of the assembly and a higher error in the out-of-training-distribution center of the assembly. This behavior as well as the differing location and magnitude of error between these variants reinforces the idea that when using these neural networks the general error behavior may be qualitatively simple but determining the actual location and magnitude of these errors is more difficult. Regardless, these results indicate the strong ability of all three variants to perform inference outside of their training regimes with a marginal decrease in accuracy.

Clad Temperature. While similar figures and analysis to that seen in the Moderator Density and Fuel Temperature Sections was performed for adversarial clad temperature distributions, the results were generally well-behaved except for those from the Four Corners dataset.

For all adversarial clad temperature examples which were within the training data the bulk of the error was distributed at or below 0.1%. There were some distributions where the maximum error was a significant outlier compared to the bulk distributions, but even in these cases the upper limit of these outliers was at or below 0.25%. In all cases the error appears to have been so low that there was a noticeable lack of distinct features in the plot of maximum pinwise error compared to those trends seen for other TH input distributions. Interestingly, for the Two Sides and Two Corners datasets the error appears to distributed around the same level for all three variants, however for the Discontinuity dataset LatticeNet 1.1 has the bulk of its error distributed around below 0.01% with outliers at 0.04%, roughly ten times less than the error distributions of the other variants. While some of these error distribution ranges are due to outliers, it's also interesting to observe that LatticeNet 1.0 appears to have large outliers generally randomly distributed, while LatticeNet 1.2 has outliers which seem to consistently be located at the top-left corner of the assembly.

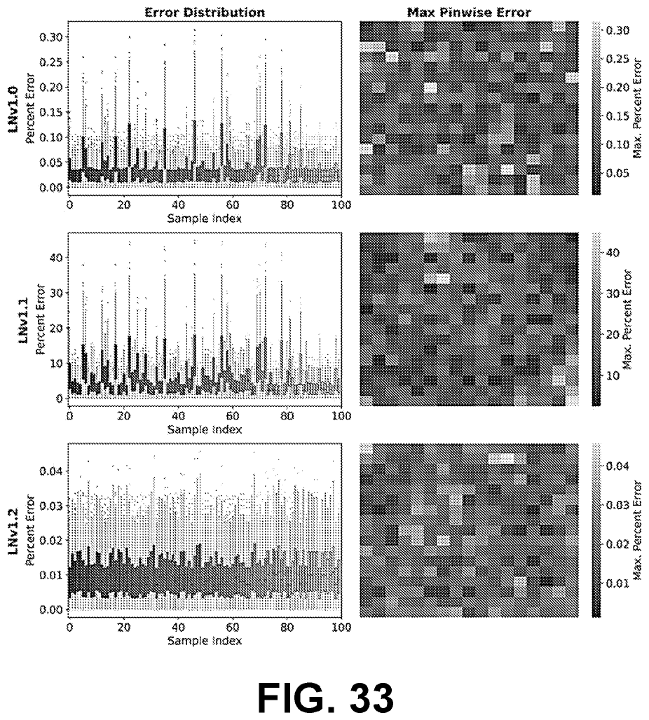

FIG. 33 shows the error distributions and maximum pinwise error for the Four Corners methodology applied to the clad temperature input. LatticeNet variants 1.0 and 1.2 behave as expected, but the error distributions for LatticeNet 1.1 are all around 5% error with outliers in the 40% error range. This is obviously not in line with expectations, and it's also non-obvious that LatticeNet 1.1 should perform so poorly when it's performed well previously, so it's worthwhile to investigate what may be causing this error.

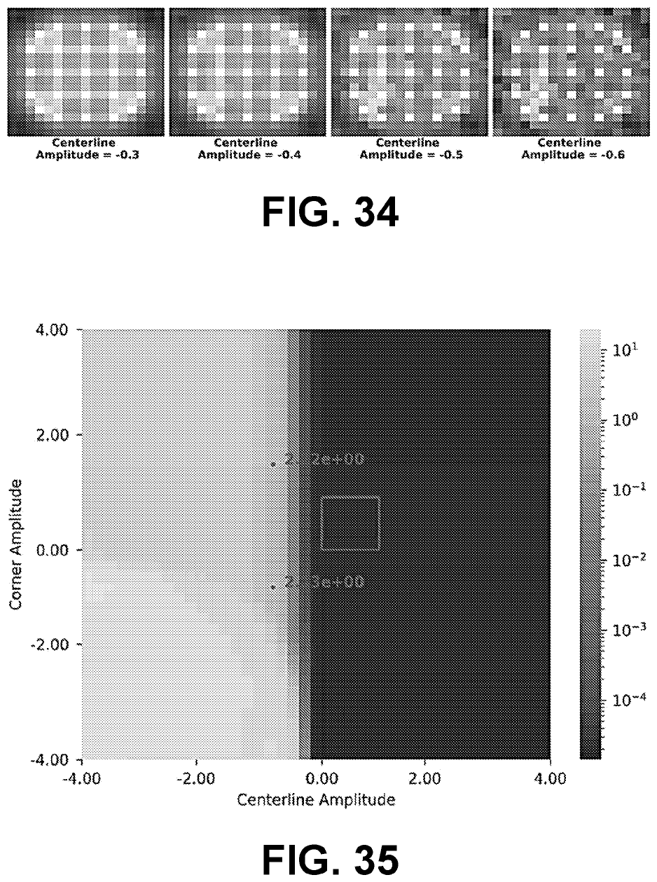

We can run some test patterns through LatticeNet 1.1 which are similar to the Four Corners dataset; that is, the corners of the input assembly are held at 1.0 (corresponding to the maximum allowed clad temperature value in the training data, 356° C.) and the amplitude of the centerline is varied between 0.0 and −1.0 (corresponding to 286° C. and 216° C., respectively). FIG. 34 shows the pin power distributions predicted by the network for these test inputs. It's evident that for centerline amplitudes approaching or below approximately −0.5, the network rapidly degrades in the quality of the answers it produces, predicting nonsense non-physical distributions as the centerline amplitude progresses lower. It appears that we've inadvertently found a vulnerability in LatticeNet to another kind of adversarial attack, one where the inputs are mathematically correct and physically valid but where the actual numerical values are so far outside of the training data that the model output becomes effectively nonsense. One explanation for this erratic behavior is that these large and negative inputs perhaps shift the the internal network state into an unstable region, since the weights are tuned to the training data and thus might be overloaded if inputs significantly different from what the network is “used to” are forward-propagated through the network.

Symmetry Testing. The results shown in FIGS. 33 and 34 indicate that LatticeNet variants may be particularly fragile w.r.t. out-of-distribution training data. While theoretically this is exactly why we would limit the usage of these models to points within the training data, it is worthwhile to develop a method which can determine apriori whether a model will produce nonsense input for known regular inputs. We describe here a simple method to accomplish this objective.

We start by devising an approach very similar to Algorithm 4, where the corners of the assembly are held at amplitude A1, the centerline is held at amplitude A2, and all other values go as a sinusoid between the corners and the assembly center. We can then vary A1 and A2 between −4 and 4, producing as many inputs as we desire which are significantly outside of the training distribution in either the positive or negative direction and which are radially symmetric. We then rotate the answer given by the network 90, 180 and 270 degrees and subtract each of these rotations from the baseline answer. Finally, we compute the sum of squared errors across all of these distributions added together. We can use this single number as a measure of whether the network is making predictions which at least appear physically valid, since given no other variations, inputs which are symmetric about the center should result in outputs which are also symmetric. This evaluation of the rotational sum of squared error (RSSE) is a quick and easy way to roughly determine whether the network is vulnerable to the kind of disruptions seen in FIG. 34, and where in the space of inputs a model is most vulnerable.

FIG. 35 shows the application of this method to the clad temperature inputs of LatticeNet 1.1. The boundaries of the original training data w.r.t. this plot are outlined with a box, the two dots indicate the maximum and minimum allowed limits of the corresponding Four Corners dataset and the text indicating the corresponding RSSE error. This plot immediately confirms what our initial analysis showed, that the network has significant and consistent trouble when the centerline input amplitude goes below −0.5, and in particular when all values go into negative regions the model appears to perform significantly worse. Interesting to note is that this trend does not hold up when the corners have a negative amplitude and the centerline is positive, and that the network is only “tricked” into producing non-physical distributions when the centerline is negative. This does not necessarily invalidate our earlier assertion that these inputs are adversarial due to their numerical range, as again LatticeNet uses convolutional layers which capture spatial behavior and thus these layers may be strongly triggering on negative inputs only within the center region of the input. Regardless, the RSSE apparently does allow us to easily predict some basic aspects of the network's behavior in out-of-distribution regimes even when we have no training data to compare against.

Evaluation of the RSSE is applied to the clad temperature inputs of the other two LatticeNet variants and is shown in FIG. 36. We see that the other variants do not display the same clear non-physical behavior for out-of-distribution data that LatticeNet 1.1 does, and indeed appear to be very well behaved out to the extremes of the data. Very similar behavior between the LatticeNet 1.0 and 1.1 plots is interesting, however it's not clear if this is because the variants converged to a similar understanding of the problem space or that both variants perform well enough to see similar error trends with the same data. Regardless, this method matches the behavior we expect given the results shown in FIG. 33 and tells us that, at least under the requirement of rotational symmetry, these variants are both well-behaved under RSSE, especially when compared to LatticeNet 1.1.

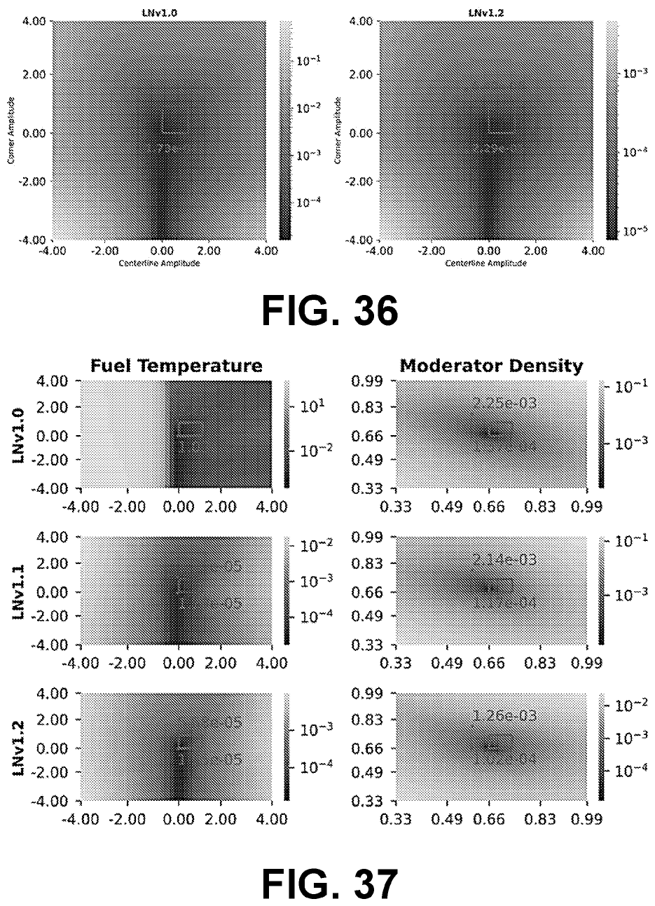

We can compute the RSSE for the previously discussed fuel temperature and moderator density inputs for all three models to see if new and interesting weaknesses in the variants manifest themselves. FIG. 37 shows the RSSE maps for ranges between −4 to 4 for the fuel temperature and 0.33 to 0.99 for the moderator density (corresponding roughly to 4× the original training data range, exactly the same as the fuel temperature and clad temperature are tested). For fuel temperature inputs, LatticeNet 1.0 appears to have developed the same fragility as LatticeNet 1.1. The reason this fragility was not caught earlier is simply because, for the fuel temperature version of the four corners dataset, the scaled inputs were very close relatively speaking to the original training data (going to a scaled input of −0.5 would have corresponded to a fuel temperature of roughly −250° C). This fragility was caught in the clad temperature case because a lower limit of 226° C. corresponds to a scaled input of roughly −0.7, far enough outside of the training data that we do encounter the “wall” where the model begins to break down. It's interesting to see that in both cases this wall appears to follow the same pattern, where the network is strongly sensitive to negative centerline amplitudes and negative corner amplitudes appear to have no effect. This may be evidence of the same mechanism driving fragility in both models, although more work is needed to confirm this.

The moderator density curves are also interesting as they don't appear to have the same out-of-distribution behavior as seen in the fuel temperature or clad temperature; that is, the symmetry error appears to be highly symmetric and biased towards uniformly extreme moderator temperatures (bottom left and top right corners). The fact that they appear to be converging to very similar RSSE values may indicate that all three of these variants ended up converging to similar understandings of the dataset and that (as far as rotational symmetry is concerned) these variants behave nearly identically. The fact that these variants behave so similarly is also a significant indicator, since (as seen in FIG. 30) all three variants explicitly do not have the same error when evaluated using real test data. Thus, we can conclude that ensuring LatticeNet gives an answer which is symmetric is necessary (but not sufficient) for gauging how well the network performs both within and outside of its initial training distribution. In the wider context of neutronics simulations, interrogating the model in this way is not novel nor (usually) needed, since any good physics code will provide a rotationally symmetric answer. However, for neural network models which have no notion of rotational symmetry and instead only pay attention to trends seen in their training data, performing this kind of analysis is important to ensure that a model is robust and for understanding where the model is likely to fail and where real physical codes are needed.

In this work we have evaluated the performance of a previously developed neural network-based machine learning model, named LatticeNet, on adversarial test samples very unlike the data used to train the model. We devised four different algorithms to generate these adversarial samples, with two going as sinusoidal variations with changing period and amplitude, one being a physical discontinuity with changing break location, and one being a curved surface with lower and upper bounds outside of the minimum and maximum ranges originally allowed in the training data. We used these algorithms to generate unique moderator density, fuel temperature and clad temperature inputs and used MPACT to compute the pin power distributions resulting from these inputs, producing 12 datasets in total, four for each TH distribution, with 100 samples each. We then supplied these adversarial TH inputs to three different LatticeNet variants and evaluated the error between the pin power distributions predicted by the variants and the ground truth calculated by MPACT. Our results show that for adversarial TH conditions within a single assembly all three LatticeNet variants are able to correctly predict the pin power distributions even for input distributions significantly outside of their training data, with the maximum error recorded at less than 1.8% and the bulk of the error at or below 0.6% for the most challenging classes of TH inputs, moderator density. We also show that the only exception to this is some variants which exhibit a vulnerability to out-of-distribution inputs as a kind of adversarial attack, and develop a simple method to test whether a network will stay physically valid for input ranges outside of its training distribution without needing to generate corresponding outputs for comparison.

While the results shown are not completely uniform between variants, they are close enough that it is difficult to say whether one variant is superior over another. We do see some qualitative evidence that the error behavior of these models are different, however more work is needed to make definitive statements on the superiority of one variant vs. another, especially with variants that have seen slightly different training data. The fact that the maximum error stayed consistently below 0.5% for more “natural” cosine inputs for all classes of TH input is encouraging, as this is approximately the same level of error expected when using more classical reconstruction-based methods. Thus, in the future with more work we are hopeful that neural network-based models will be useful in predicting pin power distributions either by themselves or as assistive subsystems for nodal-based methods. In particular, the regular and semi-continuous nature of the error generated in this paper leaves an open question as to whether error and uncertainty quantification techniques can successfully be applied to these networks in order to more effectively gauge when these models are incorrect.

The metric we use for calculating our model's physical coherency, RSSE, can easily be generalized to other machine learning models and is not specific to neural networks or to LatticeNet. We have shown here that it is highly useful in determining regions where the model is liable to break down and give physically incorrect answers, and since it uses entirely synthetic data and simple physical characteristics it can be applied anywhere by anyone. We would also like to note that this metric may be highly useful as a physics-guided approach to training the network, as rotational symmetry in the outputs given radially symmetric inputs will always be physically true and a large number of different examples of this rotational symmetry can easily be conceptualized.

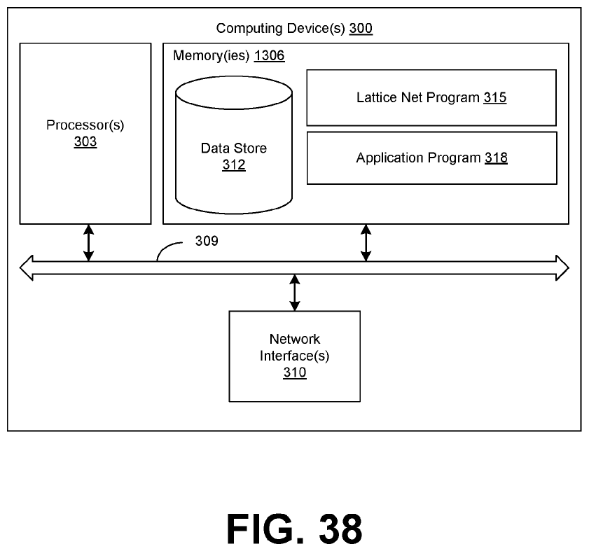

With reference to FIG. 38, shown is a schematic block diagram of a computing device 300 that can be utilized to analyze patient data for diagnosis and/or recommend treatment or prevention using the KNN techniques. In some embodiments, among others, the computing device 300 may represent a mobile device (e.g., a smartphone, tablet, computer, etc.). Each computing device 300 includes at least one processor circuit, for example, having a processor 303 and a memory 306, both of which are coupled to a local interface 309. To this end, each computing device 300 may comprise, for example, at least one server computer or like device. The local interface 309 may comprise, for example, a data bus with an accompanying address/control bus or other bus structure as can be appreciated.

In some embodiments, the computing device 300 can include one or more network interfaces 310. The network interface 310 may comprise, for example, a wireless transmitter, a wireless transceiver, and a wireless receiver. As discussed above, the network interface 310 can communicate to a remote computing device using a Bluetooth protocol. As one skilled in the art can appreciate, other wireless protocols may be used in the various embodiments of the present disclosure.

Stored in the memory 306 are both data and several components that are executable by the processor 303. In particular, stored in the memory 306 and executable by the processor 303 are a Lattice Net program 315, application program 318, and potentially other applications. Also stored in the memory 306 may be a data store 312 and other data. In addition, an operating system may be stored in the memory 306 and executable by the processor 303.

It is understood that there may be other applications that are stored in the memory 306 and are executable by the processor 303 as can be appreciated. Where any component discussed herein is implemented in the form of software, any one of a number of programming languages may be employed such as, for example, C, C++, C#, Objective C, Java®, JavaScript®, Perl, PHP, Visual Basic®, Python®, Ruby, Flash®, or other programming languages.

A number of software components are stored in the memory 306 and are executable by the processor 303. In this respect, the term “executable” means a program file that is in a form that can ultimately be run by the processor 303. Examples of executable programs may be, for example, a compiled program that can be translated into machine code in a format that can be loaded into a random access portion of the memory 306 and run by the processor 303, source code that may be expressed in proper format such as object code that is capable of being loaded into a random access portion of the memory 306 and executed by the processor 303, or source code that may be interpreted by another executable program to generate instructions in a random access portion of the memory 306 to be executed by the processor 303, etc. An executable program may be stored in any portion or component of the memory 306 including, for example, random access memory (RAM), read-only memory (ROM), hard drive, solid-state drive, USB flash drive, memory card, optical disc such as compact disc (CD) or digital versatile disc (DVD), floppy disk, magnetic tape, or other memory components.

The memory 306 is defined herein as including both volatile and nonvolatile memory and data storage components. Volatile components are those that do not retain data values upon loss of power. Nonvolatile components are those that retain data upon a loss of power. Thus, the memory 306 may comprise, for example, random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, and/or other memory components, or a combination of any two or more of these memory components. In addition, the RAM may comprise, for example, static random access memory (SRAM), dynamic random access memory (DRAM), or magnetic random access memory (MRAM) and other such devices. The ROM may comprise, for example, a programmable read-only memory (PROM), an erasable programmable read-only memory (EPROM), an electrically erasable programmable read-only memory (EEPROM), or other like memory device.

Also, the processor 303 may represent multiple processors 303 and/or multiple processor cores and the memory 306 may represent multiple memories 306 that operate in parallel processing circuits, respectively. In such a case, the local interface 309 may be an appropriate network that facilitates communication between any two of the multiple processors 303, between any processor 303 and any of the memories 306, or between any two of the memories 306, etc. The local interface 309 may comprise additional systems designed to coordinate this communication, including, for example, performing load balancing. The processor 303 may be of electrical or of some other available construction.

Although the Lattice Net program 315 and the application program 318, and other various systems described herein may be embodied in software or code executed by general purpose hardware as discussed above, as an alternative the same may also be embodied in dedicated hardware or a combination of software/general purpose hardware and dedicated hardware. If embodied in dedicated hardware, each can be implemented as a circuit or state machine that employs any one of or a combination of a number of technologies. These technologies may include, but are not limited to, discrete logic circuits having logic gates for implementing various logic functions upon an application of one or more data signals, application specific integrated circuits (ASICs) having appropriate logic gates, field-programmable gate arrays (FPGAs), or other components, etc. Such technologies are generally well known by those skilled in the art and, consequently, are not described in detail herein.

Also, any logic or application described herein, including the Lattice Net program 315 and the application program 318, that comprises software or code can be embodied in any non-transitory computer-readable medium for use by or in connection with an instruction execution system such as, for example, a processor 303 in a computer system or other system. In this sense, the logic may comprise, for example, statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system.

The computer-readable medium can comprise any one of many physical media such as, for example, magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium may be a random access memory (RAM) including, for example, static random access memory (SRAM) and dynamic random access memory (DRAM), or magnetic random access memory (MRAM). In addition, the computer-readable medium may be a read-only memory (ROM), a programmable read-only memory (PROM), an erasable programmable read-only memory (EPROM), an electrically erasable programmable read-only memory (EEPROM), or other type of memory device.

Further, any logic or application described herein, including the Lattice Net program 315 and the application program 318, may be implemented and structured in a variety of ways. For example, one or more applications described may be implemented as modules or components of a single application. Further, one or more applications described herein may be executed in shared or separate computing devices or a combination thereof. For example, a plurality of the applications described herein may execute in the same computing device 300, or in multiple computing devices in the same computing environment. Additionally, it is understood that terms such as “application,” “service,” “system,” “engine,” “module,” and so on may be interchangeable and are not intended to be limiting.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

Therefore, at least the following is claimed:

1. A method for generating neutronics parameters, comprising:
generating, by at least one computing device, a training data set based upon one or more principled approaches that provide a gradient of values;
generating, by the at least one computing device, a neural network using structured or unstructured sampling of a hyperparameter space augmented by probabilistic machine learning;
training, by the at least one computing device, the generated neural network based on the training data set to produce one or more neutronics parameters; and
generating, by the at least one computing device, at least one neutronics parameter utilizing the trained neural network.

2. The method of claim 1, wherein the structured or unstructured sampling comprises Latin hypercube sampling (LHS).

3. The method of claim 1, wherein the probabilistic machine learning comprises tree-structured Parzen estimators (TPE).

4. The method of claim 1, wherein the structured or unstructured sampling is random.

5. The method of claim 1, wherein operation of a reactor is adjusted based upon the at least one neutronics parameter.

6. The method of claim 1, further comprising testing the trained neural network based upon a defined set of input data associated with a known result.

7. The method of claim 6, wherein the known result is symmetric function about the center of the evaluated region.

8. The method of claim 7, wherein the evaluated region is a portion of a nuclear reactor core.

9. The method of claim 1, wherein data of the training data set is augmented by a lower order physical model.
